(19) United States
(12) Patent Application Publication
(10) Pub. No.: US 2025/0294848 A1
(43) Pub. Date: Sep. 18, 2025

(54) SELF-ALIGNED BACKSIDE VIA

(71) Applicant: Taiwan Semiconductor Manufacturing Company, Ltd., Hsin-Chu (TW)

(72) Inventors: Lo-Heng Chang, Hsinchu (TW); Huan-Chieh Su, Changhua County (TW); Chun-Yuan Chen, HsinChu (TW); Sheng-Tsung Wang, Hsinchu (TW); Kuo-Cheng Chiang, Hsinchu County (TW); Chih-Hao Wang, Hsinchu County (TW)

(21) Appl. No.: 18/763,851

(22) Filed: Jul. 3, 2024

Related U.S. Application Data
(60) Provisional application No. 63/565,350, filed on Mar. 14, 2024.

(51) Int. Cl. H01L 29/417; H01L 21/283; H01L 21/306; H01L 21/311; H01L 23/528; H01L 29/06; H01L 29/40; H01L 29/423; H01L 29/66; H01L 29/775; H01L 29/786

(52) U.S. Cl. CPC H10D 64/257; H01L 21/283; H01L 21/306; H01L 21/31116; H10D 62/116; H10D 64/01; H01L 23/5286; H10D 30/014; H10D 30/43; H10D 30/6735; H10D 30/6757; H10D 62/121

(57) ABSTRACT

A semiconductor structure and a method of forming the same are provided. In an embodiment, an exemplary method includes forming a sacrificial feature in a substrate, forming a source/drain feature over the sacrificial feature and protruding from the substrate, planarizing the substrate from its back to reduce its thickness, performing a first etching process to selectively remove the substrate without substantially etching the sacrificial feature, forming a dielectric layer adjacent to and under the sacrificial feature, performing a second etching process to form a trench in the dielectric layer to expose the sacrificial feature, performing a third etching process to selectively remove the sacrificial feature, and forming a conductive feature in the trench.

### PRIORITY DATA

The present application claims the benefit of U.S. Provisional Application No. 63/565,350, entitled “Backside via and methods of forming the same,” filed Mar. 14, 2024, which is herein incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as integrated circuit (IC) technologies progress towards smaller technology nodes, multi-gate devices are introduced to improve gate control by increasing gate-channel coupling, reducing off-state current, and reducing short-channel effects (SCEs). A multi-gate device generally refers to a device having a gate structure, or portion thereof, disposed over more than one side of a channel region. Fin-like field effect transistors (FinFETs) and gate-all-around (GAA) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). A GAA transistor has a gate structure that can extend, partially or fully, around a channel region to provide access to the channel region on two or more sides. The channel region of a GAA transistor may be formed from nanowires, nanosheets, other nanostructures, and/or other suitable structures. The shapes of the channel region have also given a GAA transistor alternative names such as a nanosheet transistor or a nanowire transistor.

As the dimensions of the multi-gate devices shrink, packing all contact features on one side of a substrate is becoming more and more challenging. To ease the packing density, routing features may be moved to a backside of the substrate. Such routing features may include backside vias. While existing backside via formation processes may be generally adequate for their intended purposes, they are not satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flow chart of a method for forming a semiconductor structure having a backside via, according to one or more aspects of the present disclosure.

FIGS. 2A, 3A, 4A, 5A, 6A, 7A, 8A, 9A, 10A, 11A, 12A, 13A, 14A, 15A, 16A, and 17A illustrate fragmentary perspective views of a semiconductor structure during various fabrication stages in the method of FIG. 1, according to one or more aspects of the present disclosure.

FIGS. 2B, 3B, 4B, 5B, 6B, 7B, 8B, 9B, 10B, 11B, 12B, 13B, 14B, 15B, 16B, 17B, and 18 illustrate fragmentary cross-sectional views of the semiconductor structure during various fabrication stages in the method of FIG. 1, according to one or more aspects of the present disclosure.

FIG. 19 illustrates a flow chart of a first alternative method for forming a semiconductor structure having a backside via, according to one or more aspects of the present disclosure.

FIGS. 20, 21, 22, 23, 24, 25, 26A and 26B illustrate fragmentary cross-sectional views of a semiconductor structure during various fabrication stages in the method of FIG. 19, according to one or more aspects of the present disclosure.

FIG. 27 illustrates a flow chart of a second alternative method for forming a semiconductor structure having a backside via, according to one or more aspects of the present disclosure.

FIGS. 28A, 29A, 30A, 31A, 32A, 33A, 34A, and 35A illustrate fragmentary perspective views of a semiconductor structure during various fabrication stages in the method of FIG. 27, according to one or more aspects of the present disclosure.

FIGS. 28B, 29B, 30B, 31B, 32B, 33B, 34B, 35B, and 36 illustrate fragmentary cross-sectional views of the semiconductor structure during various fabrication stages in the method of FIG. 27, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

Source/drain contacts and gate contacts of transistors on a substrate connect source/drain features of the transistors to an interconnect structure over a front side of the substrate. As the dimensions of IC devices shrink, the close proximity among the source/drain contacts and gate contacts may reduce process windows for forming these contacts and may increase parasitic capacitance among them. Backside power rail (BPR) structure is a modern solution to ease the crowding of contacts. In some schemes, backside vias may be formed from a back side of the substrate and to couple source/drain features to a backside power rail. In some existing technologies, forming non-self-aligned backside vias may involve performing photolithography for patterning. However, alignment overlay (e.g., overlay shift) associated with the patterning may lead to electrical short between the backside vias and adjacent gate structures. Forming self-aligned backside vias may solve this problem. However, existing technologies for forming self-aligned backside vias may involve forming a deep trench in source/drain regions, which may be very challenging for forming semiconductor devices with reduced pitches.

The present disclosure provides a method for forming a self-aligned backside source/drain via without forming a deep trench in the source/drain region. In an exemplary method, a shallow trench is formed in the source/drain region. A sacrificial semiconductor feature may be formed to fill a lower portion of the shallow trench, and a source/drain feature may be formed to fill an upper portion of the shallow trench. After forming functional gate structures and interconnects over the front side of the substrate, the substrate is replaced by a dielectric layer, a first etching process is then performed to form a trench exposing the sacrificial semiconductor feature, a second etching process is followed to selectively remove the sacrificial semiconductor feature to extend the trench. Backside via is then formed under the source/drain feature and in the extended trench. Thus, a self-aligned backside via may be formed without forming a deep trench in the source/drain region, and overlay window of the photolithography process for forming the trench may be relaxed, which may facilitate the scaling down of the gate-to-gate pitch.

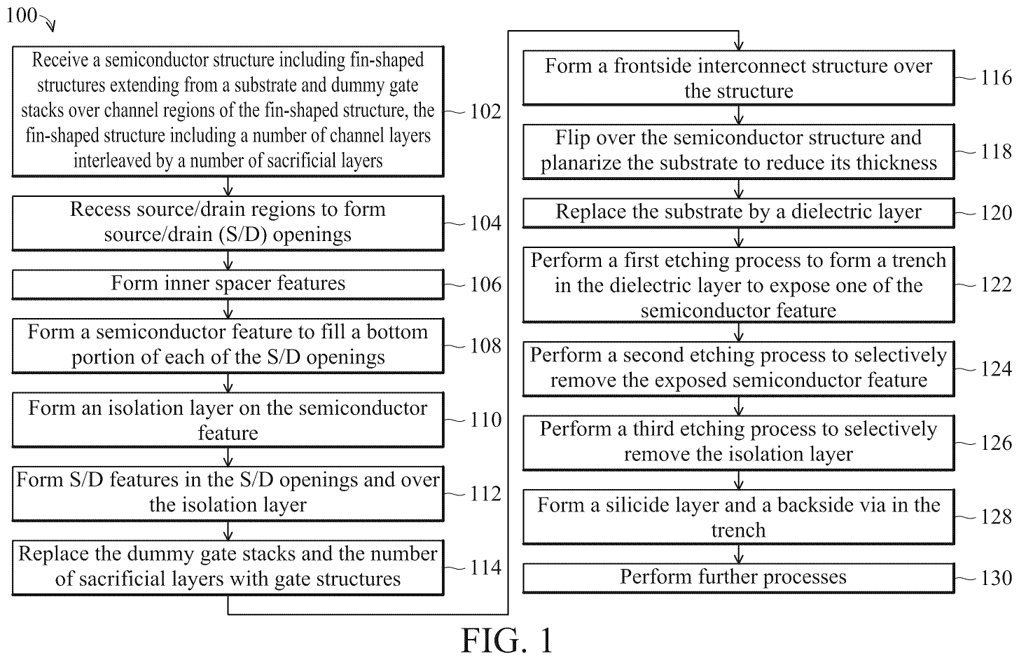

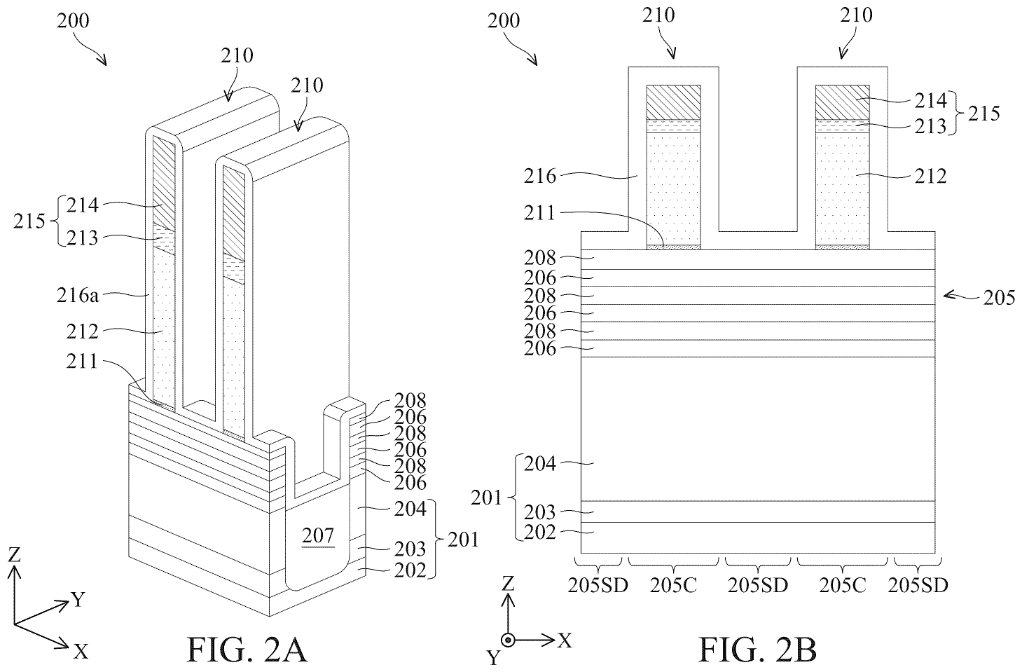

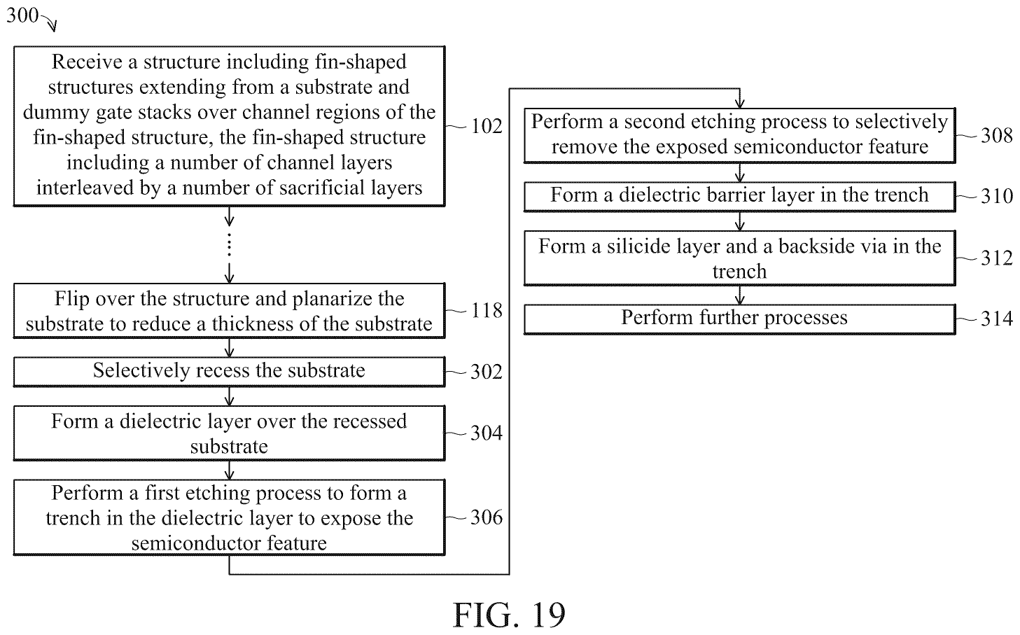

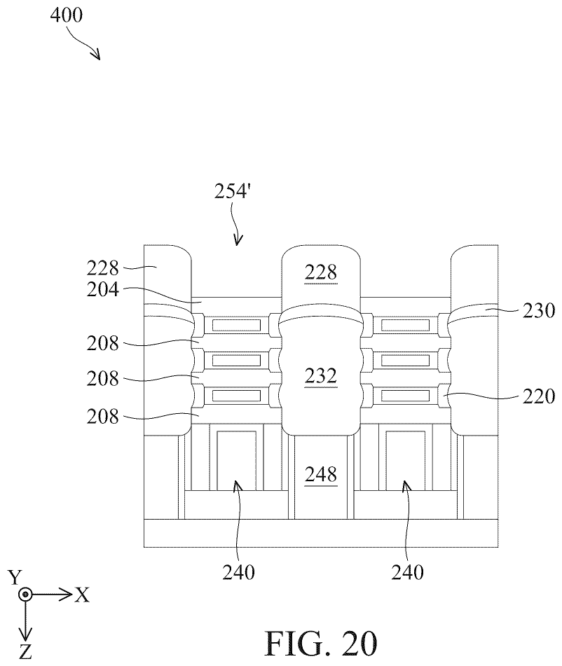

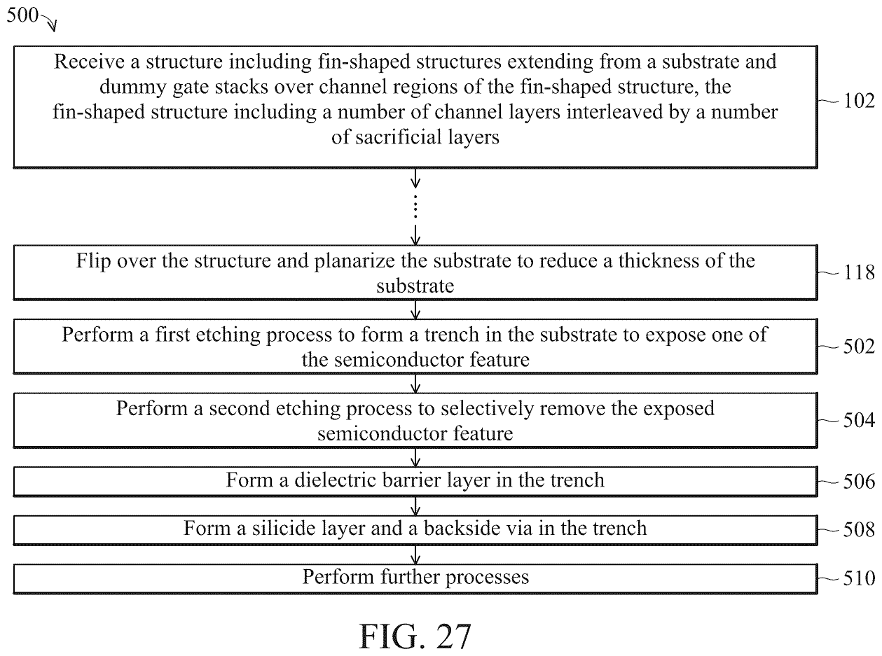

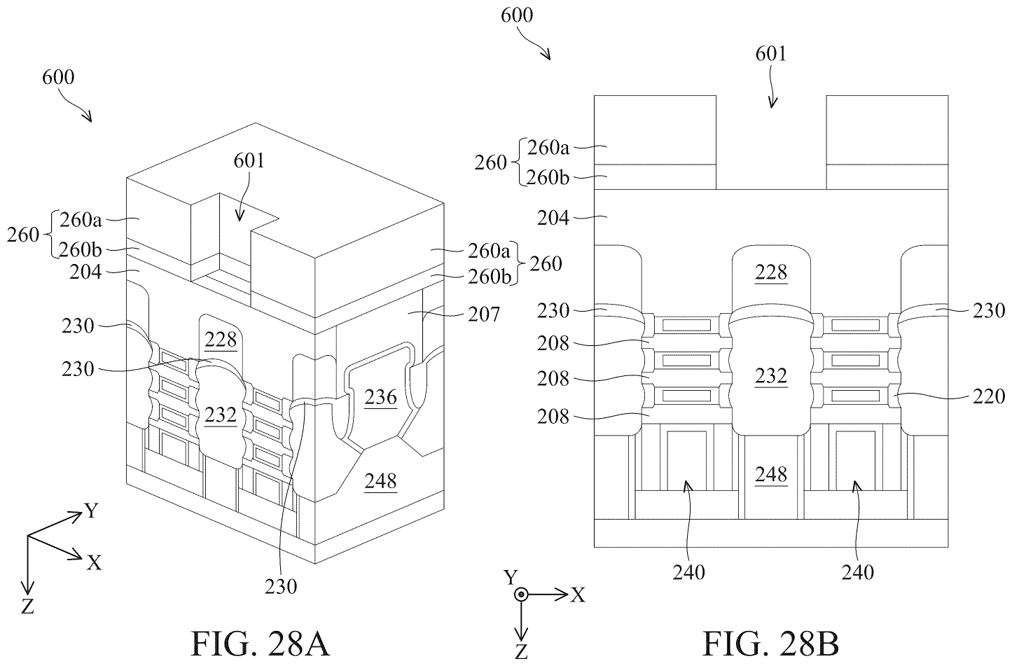

The various aspects of the present disclosure will now be described in more detail with reference to the figures. In that regard, FIG. 1 is a flowchart illustrating method 100 of forming a semiconductor structure 200 according to embodiments of the present disclosure. Method 100 is described below in conjunction with FIGS. 2A-18, which are fragmentary perspective views or cross-sectional views of the semiconductor structure 200 at different stages of fabrication according to embodiments of method 100. FIG. 19 is a flowchart illustrating method 300 of forming a semiconductor structure 400 according to embodiments of the present disclosure. Method 300 is described below in conjunction with FIGS. 20-26B, which are fragmentary cross-sectional views of the semiconductor structure 400 at different stages of fabrication according to embodiments of method 300. FIG. 27 is a flowchart illustrating method 500 of forming a semiconductor structure 600 according to embodiments of the present disclosure. Method 500 is described below in conjunction with FIGS. 28A-36, which are fragmentary perspective views or cross-sectional views of the semiconductor structure 600 at different stages of fabrication according to embodiments of method 500. Methods 100, 300, 500 are merely example and are not intended to limit the present disclosure to what is explicitly illustrated therein. Additional steps may be provided before, during, and/or after the methods 100, 300, 500, and some steps described can be replaced, eliminated, or moved around for additional embodiments of the method. Not all steps are described herein in detail for reasons of simplicity. For avoidance of doubts, the X, Y and Z directions in FIGS. 2A-36 are perpendicular to one another and are used consistently. Throughout the present disclosure, like reference numerals denote like features unless otherwise excepted.

Referring to FIGS. 1 and 2A-2B, method 100 includes a block 102 where a semiconductor structure 200 is received. The semiconductor structure 200 includes a substrate 201. In some embodiments, the substrate 201 is a bulk silicon substrate (i.e., including bulk single-crystalline silicon). The substrate 201 may include other semiconductor materials in various embodiments, such as germanium, silicon carbide, gallium arsenide, gallium phosphide, indium phosphide, indium arsenide, indium antimonide, SiGe, GaAsP, AlInAs, AlGaAs, GaInAs, GaInP, GaInAsP, or combinations thereof, or other suitable materials. In some alternative embodiments, the substrate 201 may be a semiconductor-on-insulator substrate, such as a silicon-on-insulator (SOI) substrate, a silicon germanium-on-insulator (SGOI) substrate, or a germanium-on-insulator (GOI) substrate. Semiconductor-on-insulator substrates can be fabricated using separation by implantation of oxygen (SIMOX), wafer bonding, and/or other suitable methods. In this depicted embodiment, the substrate 201 is an SOI substrate and includes a carrier layer 202, an insulator layer 203 on the carrier layer 202, and a semiconductor layer 204 on the insulator layer 203. In some embodiments, the semiconductor layer 204 may be silicon, silicon germanium, germanium, or other suitable materials and may be undoped or unintentionally doped with a very low dose of dopants. In this depicted example, the carrier layer 202 includes silicon, the insulator layer 203 includes silicon oxide, and the semiconductor layer 204 includes silicon (i.e., single-crystalline silicon).

The semiconductor structure 200 also includes fin-shaped structures 205 over the substrate 201. Each fin-shaped structure 205 extends lengthwise along the X direction and is divided into channel regions 205C overlapped by dummy gate stacks 210 and source/drain regions 205SD not covered by the dummy gate stacks 210. Source/drain region(s) 205SD may refer to a source region or a drain region, individually or collectively dependent upon the context. Each of the channel regions 205C is disposed between two source/drain regions 205SD along the X direction. The fin-shaped structure 205 may be formed from a portion of the semiconductor layer 204 and a vertical stack of alternating semiconductor layers 206 and 208 using a combination of lithography and etch steps. An exemplary lithography process includes spin-on coating a photoresist layer, soft baking of the photoresist layer, mask aligning, exposing, post-exposure baking, developing the photoresist layer, rinsing, and drying (e.g., hard baking). In some instances, the patterning of the fin-shaped structure 205 may be performed using double-patterning or multi-patterning processes to create patterns having pitches smaller than what is otherwise obtainable using a single, direct photolithography process. The etching process can include dry etching, wet etching, and/or other suitable processes. In the depicted embodiment, the vertical stack of alternating semiconductor layers 206 and 208 may include a number of channel layers 208 interleaved by a number of sacrificial layers 206. Each of the channel layers 208 may be formed of silicon (Si) and each of the sacrificial layers 206 may be formed of silicon germanium (SiGe). The channel layers 208 and the sacrificial layers 206 may be epitaxially deposited on the substrate 201 using molecular beam epitaxy (MBE), vapor-phase epitaxy (VPE), ultra-high vacuum chemical vapor deposition (UHV-CVD), and/or other suitable epitaxial growth processes.

As shown in FIG. 2B, the semiconductor structure 200 also includes an isolation feature 207 around the fin-shaped structure 205 to isolate the fin-shaped structure 205 from an adjacent fin-shaped structure 205. In some embodiments, the isolation feature 207 is deposited in trenches that define the fin-shaped structure 205. Such trenches may extend through the channel layers 208 and sacrificial layers 206 and terminate in the substrate 201. The isolation feature 207 may also be referred to as a shallow trench isolation (STI) feature 207. In an exemplary process, a dielectric material for the isolation feature is deposited over the semiconductor structure 200 using chemical vapor deposition (CVD), sub-atmospheric CVD (SACVD), flowable CVD (FCVD), physical vapor deposition (PVD), spin-on coating, and/or other suitable process. Then, the deposited dielectric material is planarized and recessed until the fin-shaped structure 205 rises above the isolation feature 207. The dielectric material for the isolation feature 207 may include silicon oxide, silicon oxynitride, fluorine-doped silicate glass (FSG), a low-k dielectric, combinations thereof, and/or other suitable materials.

Still referring to FIGS. 2A-2B, the semiconductor structure 200 also includes dummy gate stacks 210 disposed over channel regions 205C of the fin-shaped structure 205. Two dummy gate stacks 210 are shown in FIGS. 2A-2B but the semiconductor structure 200 may include more dummy gate stacks 210. In this embodiment, a gate replacement process (or gate-last process) is adopted where the dummy gate stacks 210 serve as placeholders for functional gate structures 240. Other processes and configuration are possible. The dummy gate stack 210 includes a dummy dielectric layer 211, a dummy gate electrode layer 212 over the dummy dielectric layer 211, and a gate-top hard mask layer 215 over the dummy gate electrode layer 212. The dummy dielectric layer 211 may include silicon oxide. The dummy gate electrode layer 212 may include polysilicon. The gate-top hard mask layer 215 may be a multi-layer that includes a silicon oxide layer 213 and a silicon nitride layer 214 on the silicon oxide layer 213. Suitable deposition process, photolithography and etching process may be employed to form the dummy gate stack 210.

As shown in FIGS. 2A-2B, the semiconductor structure 200 also includes a gate spacer layer 216 disposed over the semiconductor structure 200. The gate spacer layer 216 may be a single layer or a multi-layer structure. In an embodiment, the gate spacer layer 216 includes a first spacer layer and a second spacer layer deposited conformally over the semiconductor structure 200, including over top surfaces and sidewalls of the dummy gate stacks 210 and top surfaces of the fin-shaped structure 205. The term “conformally” may be used herein for ease of description of a layer having a substantially uniform thickness over various regions. In some embodiments, the gate spacer layer 216 may include silicon oxide, silicon oxycarbide, silicon carbonitride, silicon nitride, zirconium oxide, aluminum oxide, or a suitable dielectric material and may be deposited over the dummy gate stacks 210 using processes such as, CVD, SACVD, FCVD, atomic layer deposition (ALD), PVD, or other suitable process.

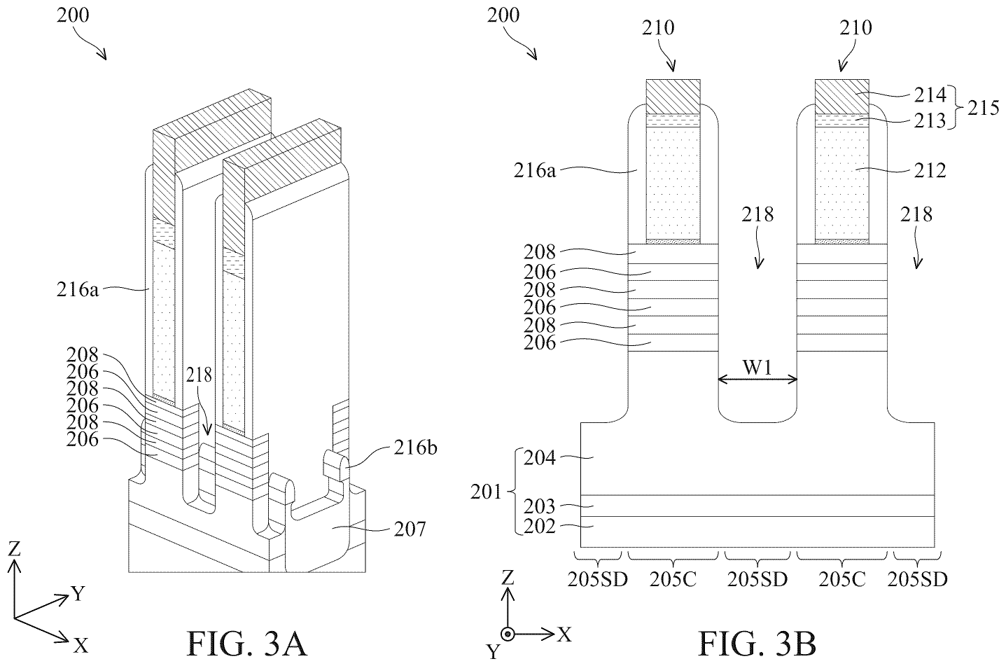

Referring to FIGS. 1 and 3A-3B, method 100 includes a block 104 where source/drain regions 205SD of the fin-shaped structure 205 are recessed to form source/drain openings 218. In an embodiment, an etching process is performed to etch back the gate spacer layer 216, thereby forming gate spacers 216a extending along sidewall surfaces of the dummy gate stacks 210. The etch back of the gate spacer layer 216 further forms fin sidewalls spacers 216b (shown in FIG. 3A) extending along lower portions of the fin-shaped structures 205. The source/drain regions 205SD of the fin-shaped structure 205 that are not covered by the dummy gate stack 210 and the gate spacers 216a may be anisotropically etched by a dry etch or a suitable etching process to form the source/drain openings 218. An exemplary dry etching process may implement an oxygen-containing gas, hydrogen, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. In embodiments represented in FIGS. 3A-3B, the source/drain openings 218 extend through vertical stack of channel layers 208 and sacrificial layers 206 and extend into the semiconductor layer 204 of the substrate 201. A lower portion of the source/drain opening 218 extended into the substrate 201 spans a width W1. In an embodiment, the width W1 is in a range between about 8 nm and about 40 nm. In some embodiments, etching processes implemented for the etch back of the gate spacer layer 216 and/or the formation of the source/drain openings 218 may slightly etch the isolation feature 207. For example, as represented by FIG. 3A, portions of the isolation feature 207 not covered by the fin sidewall spacers 216b are slightly recessed. As illustrated in FIGS. 3A-3B, sidewalls of the channel layers 208 and the sacrificial layers 206 are exposed in the source/drain openings 218.

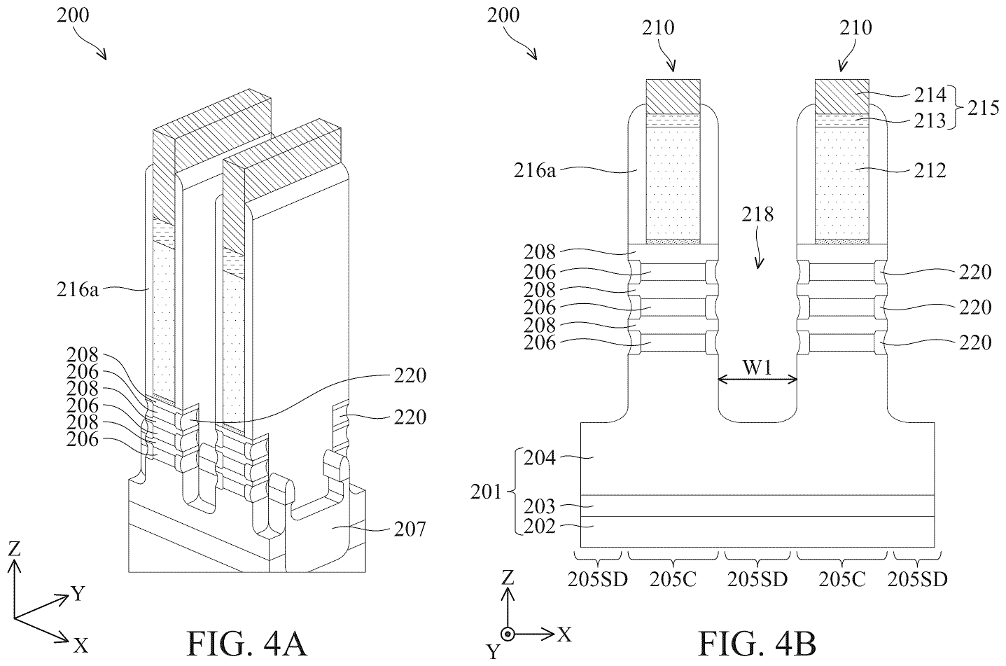

Referring to FIGS. 1 and 4A-4B, method 100 includes a block 106 where inner spacer features 220 are formed. After the formation of the source/drain openings 218, the sacrificial layers 206 exposed in the source/drain openings 218 are selectively and partially recessed to form inner spacer recesses (not shown), while the exposed channel layers 208 are not significantly etched. In an embodiment where the channel layers 208 consist essentially of silicon (Si) and sacrificial layers 206 consist essentially of silicon germanium (SiGe), the selective and partial recess of the sacrificial layers 206 may include use of a selective isotropic etching process (e.g., a selective dry etching process or a selective wet etching process), and the extent at which the sacrificial layers 206 are recessed is controlled by duration of the etching process. After the formation of the inner spacer recesses, an inner spacer material layer is deposited over the semiconductor structure 200, including in the inner spacer recesses. The inner spacer material layer may include silicon oxide, silicon nitride, silicon oxycarbide, silicon oxycarbonitride, silicon carbonitride, metal nitride, or a suitable dielectric material. The deposited inner spacer material layer is then etched back to remove excessive inner spacer material layer over sidewalls of the channel layers 208, thereby forming the inner spacer features 220 as shown in FIGS. 4A-4B.

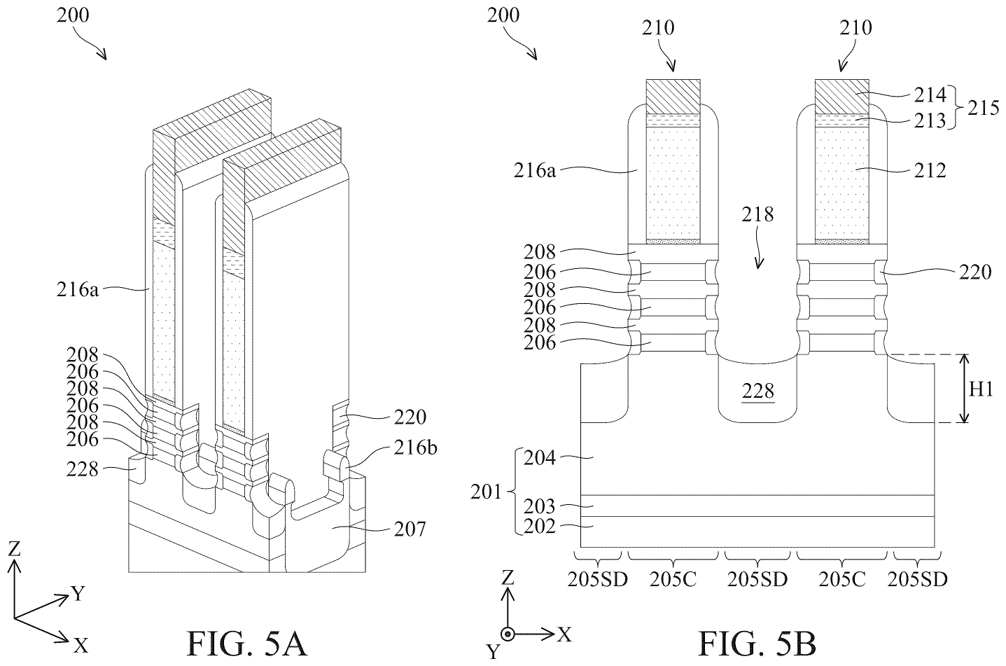

Referring to FIGS. 1 and 5A-5B, method 100 includes a block 108 where a semiconductor feature 228 is formed in the source/drain opening 226. The semiconductor feature 228 may be selectively formed in the lower portion of the source/drain opening 218 using molecular beam epitaxy (MBE), vapor-phase epitaxy (VPE), ultra-high vacuum CVD (UHV-CVD)), and/or other suitable epitaxial growth processes. The composition of the semiconductor feature 228 is different from that of the semiconductor layer 204 such that the semiconductor layer 204 may be selectively removed in a subsequent process. For example, when the semiconductor layer 204 is formed of silicon, the semiconductor feature 228 may include SiGe, boron-doped SiGe (SiGe:B), or other suitable material such that the semiconductor layer 204 may be selectively removed without substantially etching the semiconductor feature 228. In an embodiment, the semiconductor layer 204 is formed of silicon and the semiconductor feature 228 is formed of SiGe. Germanium concentration of the SiGe-based semiconductor feature 228 may be in a range between about 10% and about 50%. If the germanium concentration is less than about 10%, the etch selectivity between the semiconductor feature 228 and the semiconductor layer 204 may not be high enough to provide satisfactory etching result; if the germanium concentration is greater than about 50%, duration for removing the SiGe-based semiconductor feature 228 may be prolonged, and it may also be difficult to epitaxially growth source/drain feature thereover.

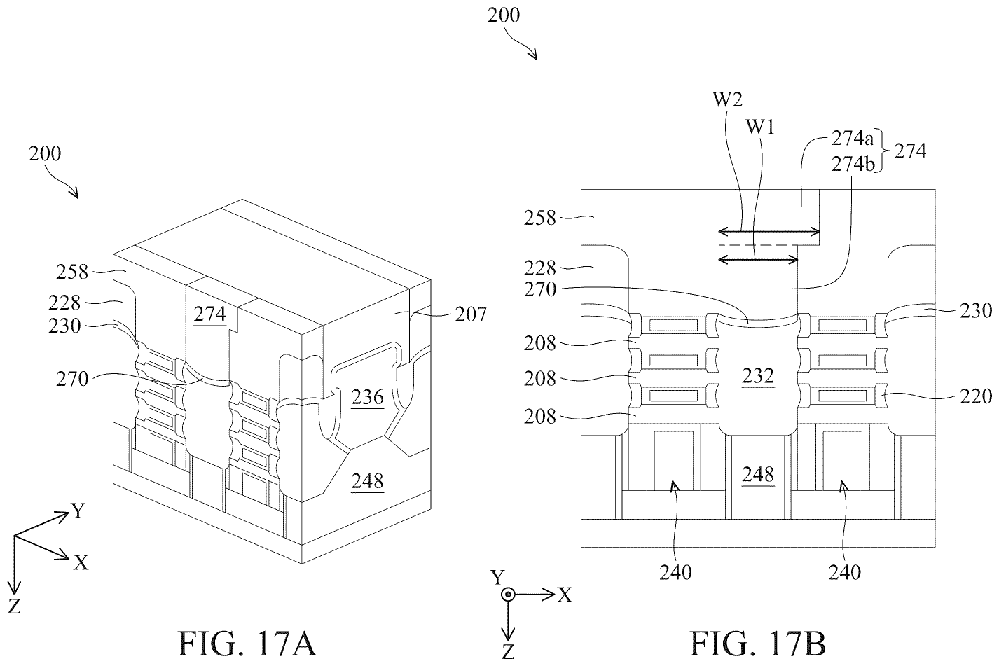

The semiconductor feature 228 has a height H1 along the Z direction. In some embodiments, a ratio of the height H1 of the semiconductor feature 228 to a width (i.e., W1) of the semiconductor feature 228 may be in a range between about 0.3 and about 3. If the ratio is greater than about 3, as described above, dimensions of the multi-gate devices shrink, gate pitch also reduces, it would be challenging to form deep source/drain openings for devices having reduced pitches; if the ratio is less than about 0.3, a portion (e.g., the portion 274a shown in FIG. 17B) of the to-be-formed backside via will be too close to the functional gate structure, undesirably leading to an increased parasitic capacitance. In an embodiment, the height H1 is in a range between about 2 nm and 30 nm. If the height H1 is greater than about 30 nm, as described above, dimensions of the multi-gate devices shrink, gate pitch also reduces, it would be challenging to form deep source/drain openings. If the height H1 is less than about 2 nm, a portion of the to-be-formed backside via will be too close to the functional gate structure, undesirably leading to an increased parasitic capacitance and an increased electrical short risk. In an embodiment, the top surface of the semiconductor feature 228 has a dishing profile that has a concave shape having a depth at its deepest portion. In some embodiments, the depth is about nm to about 5 nm. Since one or more of the semiconductor features 228 may be removed during subsequent processes, the semiconductor feature 228 may also be referred to as sacrificial feature 228 or sacrificial semiconductor feature 228.

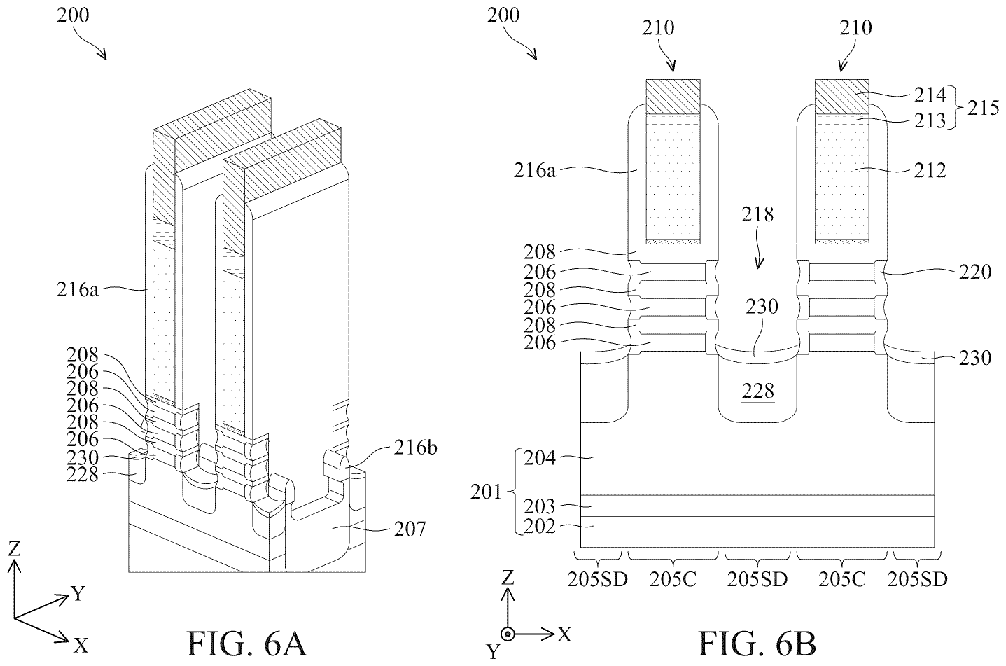

Referring to FIGS. 1 and 6A-6B, method 100 includes a block 110 where an isolation layer 230 is formed on the semiconductor feature 228 and in the source/drain opening 226. The isolation layer 230 may be formed of any suitable dielectric material so long as its composition is different from those of the channel layers 208, the sacrificial layers 206, the gate-top hard mask layer 215, the gate spacers 216a, and the inner spacer features 220 to allow selective removal by an etching process. In some embodiments, the isolation layer 230 may include silicon nitride (SiN), silicon oxynitride (SiON), silicon oxycarbonitride (SiOCN), silicon oxycarbide (SiOC), silicon carbonitride (SiCN), aluminum oxide, hafnium oxide, or other suitable materials. In an embodiment, the isolation layer 230 is oxygen-free and includes silicon nitride. In some other embodiments, the layer 230 may be a semiconductor layer such a silicon layer or a boron doped silicon layer (Si:B). Although not shown, in some embodiments, the isolation layer 230 may also be formed on the top surface of the horizontal portion (along the Y direction) of the recessed isolation feature 207. In this illustrated embodiment, a topmost surface of the isolation layer 230 is lower than or coplanar with a bottom surface of a bottommost channel layer 208 of the channel layers 208. In an embodiment, the isolation layer 230 is in direct contact with a bottommost inner spacer feature 220 of the inner spacer features 220. In some other alternative embodiments, the isolation layer 230 has a top surface lower than a topmost surface of the substrate 201. A thickness of the isolation layer 230 may be in a range between about 2 nm and about 5 nm. If the thickness is less than 2 nm, it may not be able to reduce or eliminate potential current leakage between the source/drain feature 232 and the semiconductor layer 204; if the thickness is greater than 5 nm, it may be too thick to be effectively removed by a subsequent etching process 268. It is noted that the isolation layer 230 is optional. The semiconductor structure 200 may not include this isolation layer 230.

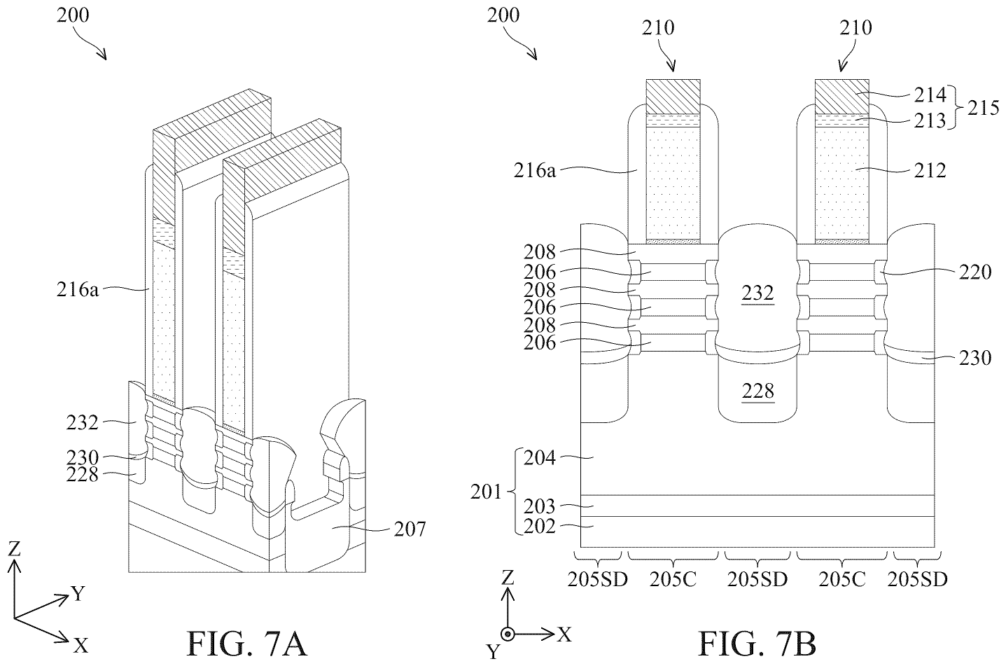

Referring to FIGS. 1 and 7A-7B, method 100 includes a block 112 where source/drain features 232 are formed in the source/drain openings 218. Source/drain feature(s) 232 may refer to a source or a drain, individually or collectively dependent upon the context. The source/drain features 232 each may be epitaxially and selectively formed from exposed sidewalls of the channel layers 208 by using an epitaxial process, such as vapor phase epitaxy (VPE), ultrahigh vacuum chemical vapor deposition (UHV-CVD), molecular-beam epitaxy (MBE), and/or other suitable processes. The source/drain features 232 may include N-type source/drain features and/or P-type source/drain features dependent upon types of transistors. Exemplary N-type source/drain features may include silicon, phosphorus-doped silicon, arsenic-doped silicon, antimony-doped silicon, or other suitable material and may be in-situ doped during the epitaxial process by introducing an N-type dopant, such as phosphorus, arsenic, or antimony, or ex-situ doped using a junction implant process. Exemplary P-type source/drain features may include germanium, gallium-doped silicon germanium, boron-doped silicon germanium, or other suitable material and may be in-situ doped during the epitaxial process by introducing a P-type dopant, such as boron or gallium, or ex-situ doped using a junction implant process. Dopant concentration of the N-type source/drain feature or P-type source/drain feature may be in a range between about 5E19/cm³ and about 5E21/cm³. In some embodiments, each of the source/drain features 232 may include multiple semiconductor layers with different doping concentrations. For example, each of the source/drain features 232 may include a lightly doped semiconductor layer and a heavily doped semiconductor layer disposed over the lightly doped semiconductor layer.

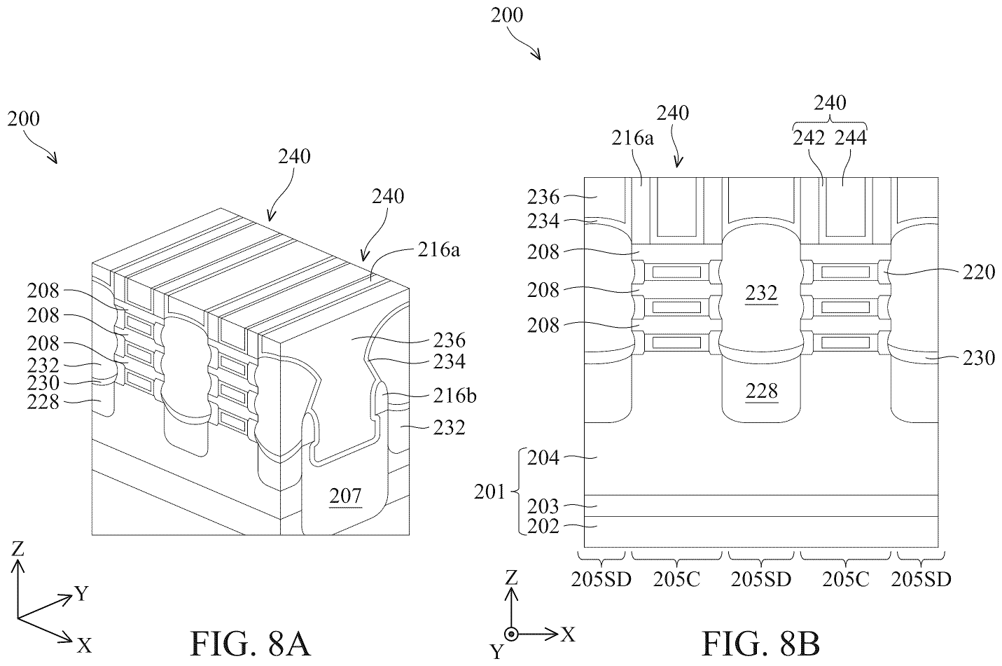

Referring to FIGS. 1 and 8A-8B, method 100 includes a block 114 where the dummy gate stacks 210 and the sacrificial layers 206 are replaced by gate structures 240. In this embodiment, a contact etch stop layer (CESL) 234 and an interlayer dielectric (ILD) layer 236 are deposited over the semiconductor structure 200. The CESL 234 may include silicon nitride, silicon oxynitride, and/or other materials known in the art and may be formed by ALD, plasma-enhanced chemical vapor deposition (PECVD) process and/or other suitable deposition or oxidation processes. As shown in FIGS. 8A-8B, the CESL 234 may be deposited on top surfaces of the source/drain features 232 and sidewalls of the gate spacers 216a. The ILD layer 236 is deposited by a PECVD process or other suitable deposition technique over the semiconductor structure 200 after the deposition of the CESL 234. The ILD layer 236 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. In some embodiments, after formation of the ILD layer 236, the semiconductor structure 200 may be annealed to improve integrity of the ILD layer 236. A planarization process, such a chemical mechanical polishing (CMP) process may be performed to the semiconductor structure 200 to remove excessive materials and expose top surfaces of the dummy gate electrode layer 212 in the dummy gate stacks 210.

With the exposure of the dummy gate electrode layer 212, block 114 proceeds to removal of the dummy gate stacks 210. The removal of the dummy gate stacks 210 may include one or more etching process that are selective to the material in the dummy gate stacks 210. For example, the removal of the dummy gate stacks 210 may be performed using a selective wet etch, a selective dry etch, or a combination thereof. After the removal of the dummy gate stacks 210, the sacrificial layers 206 are selectively removed to release the channel layers 208 as channel members 208 in the channel regions 205C. The selective removal of the sacrificial layers 206 may be implemented by a selective dry etch, a selective wet etch, or other selective etching process. In some embodiments, the selective wet etching includes an APM etch (e.g., ammonia hydroxide-hydrogen peroxide-water mixture).

The gate structures 240 are then formed to wrap over the channel members 208. Each of the gate structures 240 includes a gate dielectric layer 242 and a gate electrode layer 244 over the gate dielectric layer 242. In some embodiments, the gate dielectric layer 242 includes an interfacial layer disposed on the channel members 208 and a high-k dielectric layer over the interfacial layer. Here, a high-k dielectric layer refers to a dielectric material having a dielectric constant greater than that of silicon dioxide, which is about 3.9. A low-k dielectric layer refers to a dielectric material having a dielectric constant no greater than that of silicon dioxide. In some embodiments, the interfacial layer includes silicon oxide. The high-k dielectric layer is then deposited over the interfacial layer using ALD, CVD, and/or other suitable methods. The high-k dielectric layer may include hafnium oxide. Alternatively, the high-k dielectric layer may include other high-k dielectrics, such as titanium oxide, hafnium zirconium oxide, tantalum oxide, hafnium silicon oxide, zirconium silicon oxide, lanthanum oxide, aluminum oxide, yttrium oxide, SrTiO₃, BaTiO₃, BaZrO, hafnium lanthanum oxide, lanthanum silicon oxide, aluminum silicon oxide, hafnium tantalum oxide, hafnium titanium oxide, (Ba,Sr)TiO₃ (BST), silicon nitride, silicon oxynitride, combinations thereof, or other suitable material.

The gate electrode layer 244 is then deposited over the gate dielectric layer 242 using ALD, PVD, CVD, e-beam evaporation, or other suitable methods. The gate electrode layer 244 may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer 244 may include titanium nitride, titanium aluminum, titanium aluminum nitride, tantalum nitride, tantalum aluminum, tantalum aluminum nitride, tantalum aluminum carbide, tantalum carbonitride, aluminum, tungsten, nickel, titanium, ruthenium, cobalt, platinum, tantalum carbide, tantalum silicon nitride, copper, other refractory metals, or other suitable metal materials or a combination thereof. Further, where the semiconductor structure 200 includes n-type transistors and p-type transistors, different gate electrode layers may be formed separately for n-type transistors and p-type transistors, which may include different work function metal layers (e.g., for providing different n-type and p-type work function metal layers).

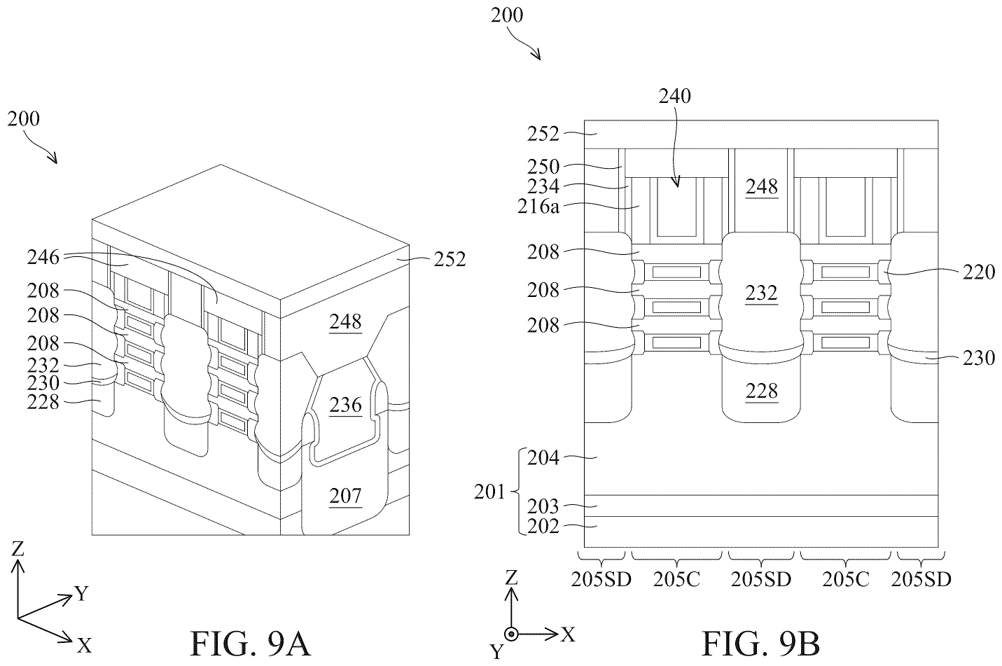

Referring to FIGS. 1 and 9A-9B, method 100 includes a block 116 where a first interconnect structure 252 is formed over the semiconductor structure 200. In an embodiment, after forming the gate structures 240, a dielectric structure 246 is formed over the ILD layer 236 and the gate structures 240. The dielectric structure 246 may include an etch stop layer and a dielectric layer deposited over the etch stop layer. The etch stop layer may be similar to the CESL 234, and the dielectric layer may be similar to the ILD layer 236 in terms of compositions and formation processes. The etch stop layer in the dielectric structure 246 may indicate an etch stop point for forming gate via openings over the gate structures 240. After forming the dielectric structure 246, silicide layers (not shown) and source/drain contacts 248 are formed over the source/drain features 232. The source/drain contacts 248 may include aluminum (Al), copper (Cu), tungsten (W), cobalt (Co), ruthenium (Ru), or molybdenum (Mo) or other suitable materials and may be formed by any suitable deposition processes (e.g., CVD). A planarization process, such as a chemical mechanical polish (CMP) process, may be then performed to remove excess portions of deposited conductive layer for forming source/drain contacts 248. In some embodiments, a dielectric barrier layer 250 may be formed to provide enhanced isolation between the gate structure 240 and its adjacent source/drain contacts 248. Gate vias may be formed to extend through the dielectric structure 246 to couple to the gate structures 240.

After forming the gate vias and the source/drain contacts 248, a first interconnect structure 252 is formed over the structure. The first interconnect structure 252 may include multiple intermetal dielectric (IMD) layers and multiple metal lines or contact vias in each of the IMD layers. In some instances, the IMD layers and the ILD layer 236 may share similar composition. The metal lines and contact vias in each IMD layer may be formed of metal, such as aluminum, tungsten, ruthenium, or copper. In some embodiments, the metal lines and contact vias may be lined by a barrier layer to insulate the metal lines and contact vias from the IMD layers and to prevent electro-migration. Because the first interconnect structure 252 is formed over the front side of the semiconductor structure 200, the first interconnect structure 252 may also be referred to as a frontside interconnect structure 252.

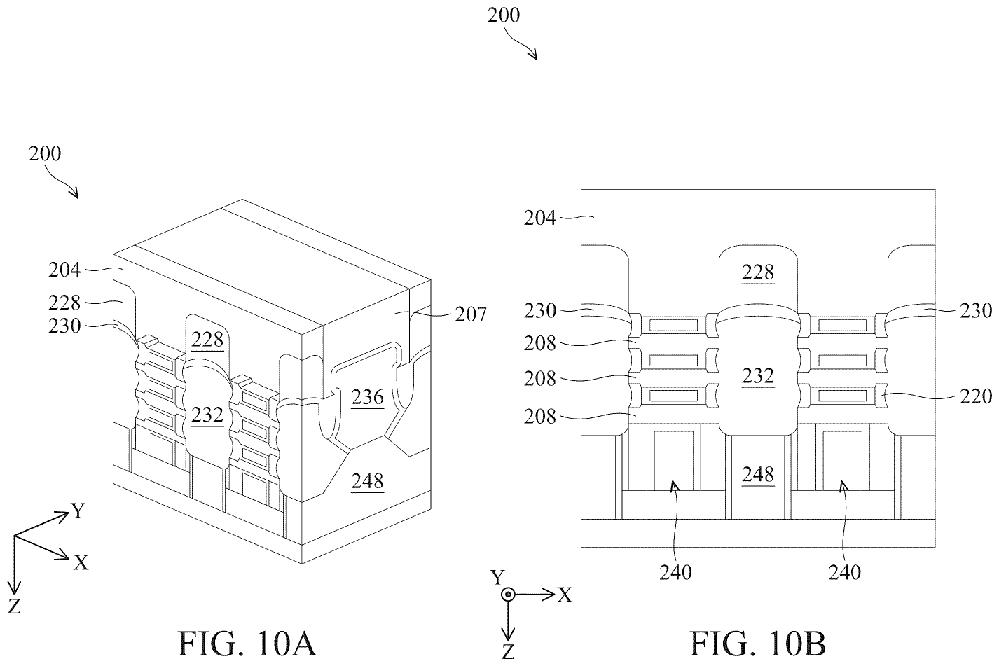

Referring to FIGS. 1 and 10A-10B, method 100 includes a block 118 where the semiconductor structure 200 is flipped over and planarized. After forming the first interconnect structure 252, a carrier substrate (not shown) is then bonded to the first interconnect structure 252 by fusion bonding, by use of an adhesion layer, or a combination thereof. In some instances, the carrier substrate may include semiconductor materials (such as silicon), sapphire, glass, polymeric materials, or other suitable materials. In embodiments where fusion bonding is used, the carrier substrate includes a bottom oxide layer and the first interconnect structure 252 includes a top oxide layer. After both the bottom oxide layer and top oxide layer are treated, they are placed in plush contact with one another for direct bonding at room temperature or at an elevated temperature. Once the carrier substrate is bonded to the first interconnect structure 252, the semiconductor structure 200 is flipped over. The back side of the semiconductor structure 200 is then planarized (e.g., by a planarization process such as a chemical mechanical poshing CMP process) to reduce a thickness of the substrate 201 from its back. In an embodiment, as depicted by FIGS. 10A-10B, the planarization process may stop until the bottom surface of the STI feature 207 is exposed. In this embodiment, the carrier layer 202 and the insulator layer 203 of the substrate 201 are removed during the planarization process. It is noted that, the planarization process does not expose the semiconductor feature 228. In some embodiments, the planarization process may also remove a portion of the STI feature 207. For ease of description, positional relationships hereafter will be described based on the structure 200 after the flipping, as depicted in the figures.

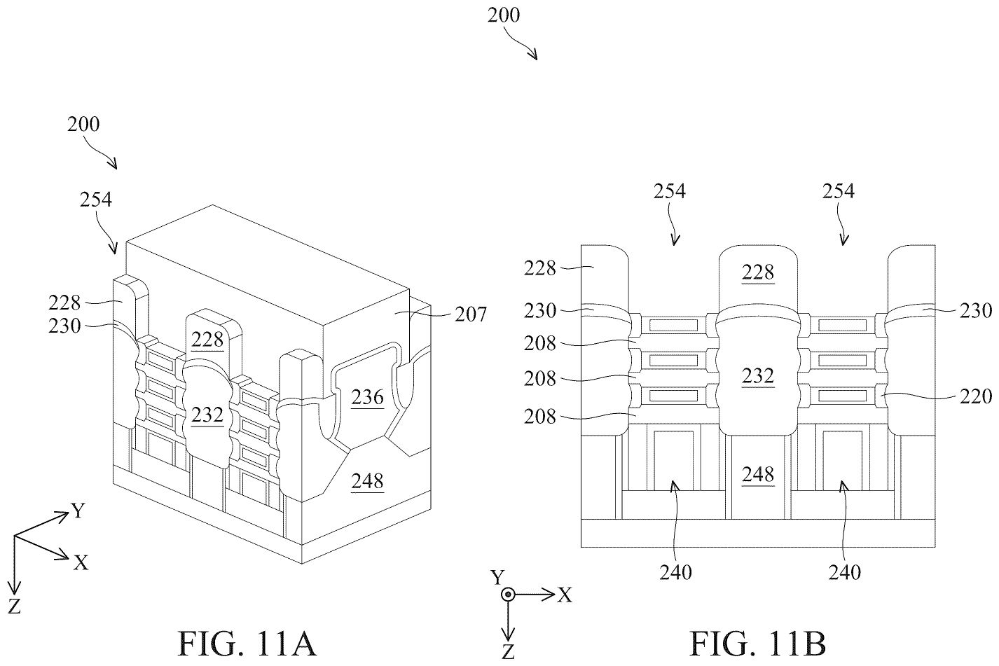

Referring to FIGS. 1, 11A-11B and 12A-12B, method 100 includes a block 120 where the semiconductor layer 204 of the substrate 201 is replaced by a dielectric layer 258. With reference to FIGS. 11A-11B, the semiconductor layer 204 is selectively and fully removed with respect to the semiconductor features 228, the STI features 207, and the gate structures 240. The removal of the semiconductor layer 204 forms an opening 254. The etching process for selectively removing the semiconductor layer 204 may be a selective wet etching process or a selective dry etching process. An exemplary selective dry etching process may implement CF₄, NF₃, Cl₂, HBr, other suitable gases and/or plasmas, and/or combinations thereof.

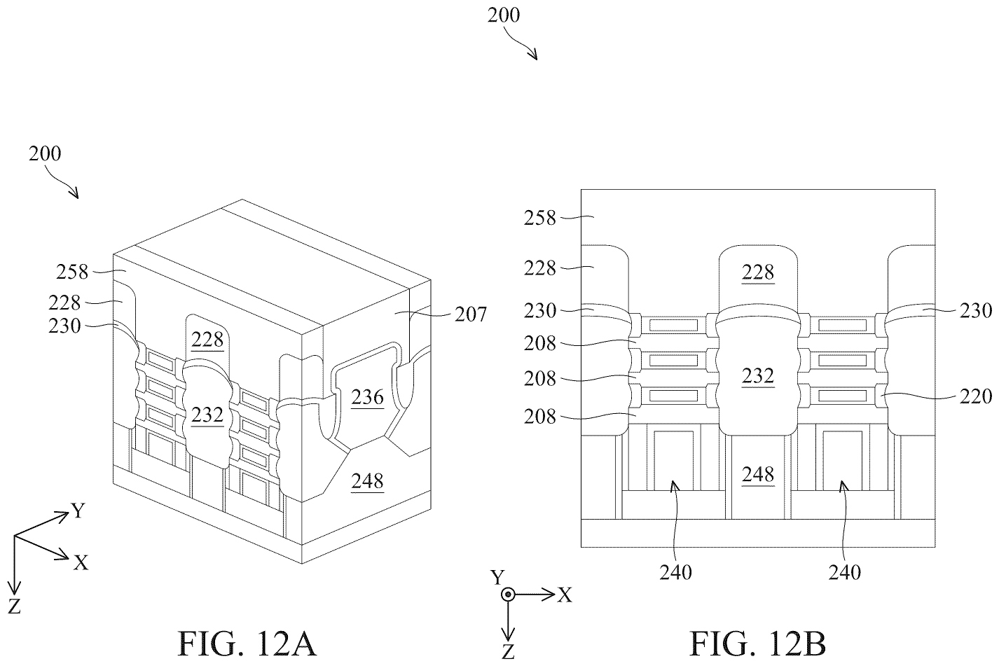

With reference to FIGS. 12A-12B, a dielectric layer 258 is then formed in the opening 254 and over the semiconductor structure 200. The dielectric layer 258 may be deposited over the back side of the semiconductor structure 200 by FCVD, CVD, PECVD, spin-on coating, or a suitable process. The dielectric layer 258 may include oxide, nitride, or other suitable materials. For example, the dielectric layer 258 may include silicon oxide, silicon oxycarbide, silicon oxycarbonitride, silicon nitride, silicon carbonitride, zirconium nitride, tantalum carbonitride, aluminum oxynitride, hafnium oxide, zirconium oxide, zirconium aluminum oxide, titanium oxide, hafnium zirconium oxide, tantalum oxide, hafnium silicon oxide, zirconium silicon oxide, lanthanum oxide, aluminum oxide, yttrium oxide, hafnium lanthanum oxide, lanthanum silicon oxide, hafnium tantalum oxide, or hafnium titanium oxide. In some embodiments, the dielectric layer 258 may include silicon oxide or have a composition similar to that of the ILD layer 236. A planarization process may be performed to planarize the back side of the semiconductor structure 200 by removing excess portions of the deposited dielectric layer 258 outside of the opening 254.

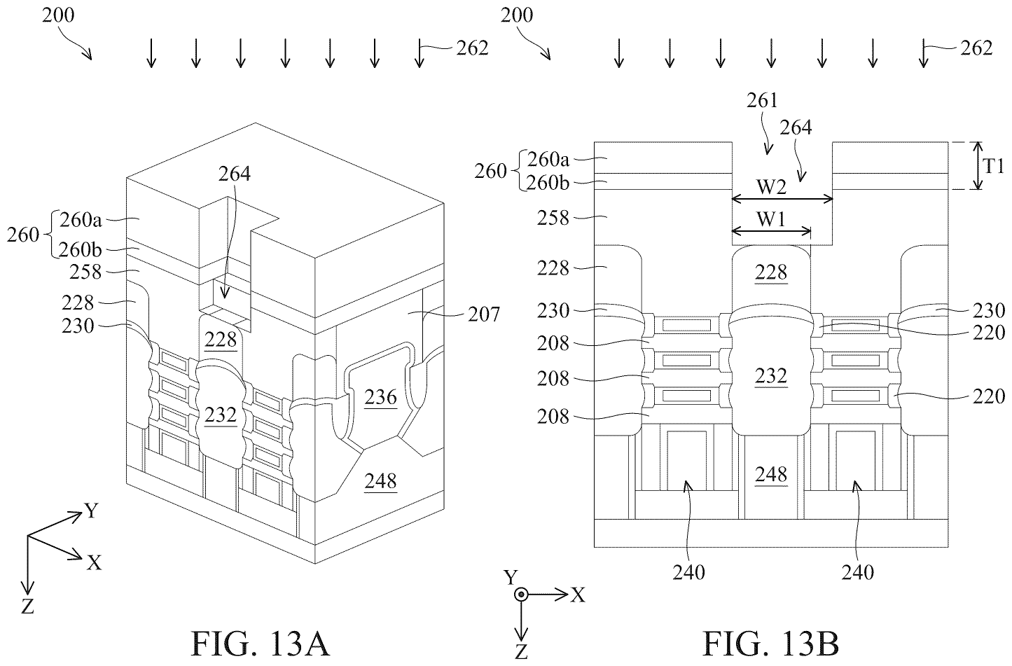

Referring to FIGS. 1 and 13A-13B, method 100 includes a block 122 where a first etching process 262 is performed to form a trench 264 in the dielectric layer 258 to expose the semiconductor feature 228. In an exemplary process, a dielectric structure 260 is formed over the back side of the semiconductor structure 200. To provide an end point for a subsequent planarization process, the dielectric structure 260 includes a first layer 260a and a second layer 260b having a material composition different than the first layer 260a. In an embodiment, the first layer 260a includes an oxide layer (e.g., silicon oxide), and the second layer 260b includes a nitride layer (e.g., silicon nitride). A thickness T1 of the patterned dielectric structure 260 may be in a range between about 5 nm and about 70 nm. If the thickness T1 is less than 5 nm, the dielectric structure 260 may be too thin to indicate an end point for subsequent planarization process for forming a backside via; if the thickness T1 is greater than 70 nm, it would increase fabrication difficulty for forming a satisfactory backside via. For example, a thick dielectric structure may lead to a longer etch duration for forming the trench 264, a deeper backside via opening, and thus increased deposition difficulty for forming layers in the deeper backside via opening. With reference to FIGS. 13A-13B, the dielectric structure 260 is patterned to form an opening 261. The opening 261 exposes a portion of the dielectric layer 258 disposed directly over the semiconductor feature 228. Although only one opening 261 is shown in FIGS. 13A-13B, the dielectric structure 260 may be patterned to form more openings 261.

After forming the patterned dielectric structure 260, while using the patterned dielectric structure 260 as an etch mask, the first etching process 262 is performed to form a trench 264 extending into the dielectric layer 258. In this illustrated embodiment, the trench 264 spans a width W2 greater than the width W1 of the semiconductor feature 228. That is, the trench 264 not only exposes the bottom surface of the semiconductor feature 228, but also exposes a portion of the dielectric layer 258 extending over the inner spacer feature 220. In an embodiment, the width W2 may be in a range between about 10 nm and about 50 nm. In this illustrated embodiment, as represent by FIG. 13A, when viewed from top, the trench 264 further exposes a portion of the STI feature 207. Similarly, although only one trench 264 is shown in FIGS. 13A-13B, the dielectric layer 258 may be etched to form more trenches 264 to expose more semiconductor features 228. The first etching process 262 may be a dry etch process that includes use of argon (Ar), a fluorine-containing etchant (for example, SF₆, NF₃, CH₂F₂, CHF₃, C₄F₈, and/or C₂F₆), an oxygen-containing etchant, a chlorine-containing etchant (for example, Cl₂, CHCl₃, CCl₄, and/or BCl₃), a bromine-containing etchant (for example, HBr and/or CHBr₃), an iodine-containing etchant, or combinations thereof. In some embodiments, the first etching process 262 may be an anisotropic etch.

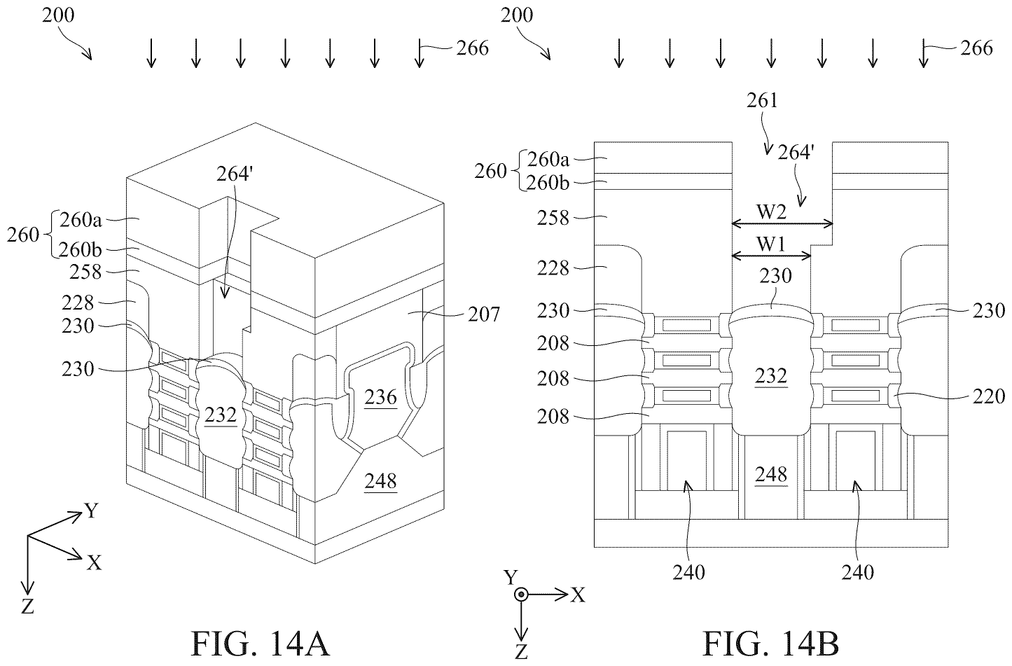

Referring to FIGS. 1 and 14A-14B, method 100 includes a block 124 where a second etching process 266 is performed to selectively remove the semiconductor feature 228. After forming the trench 264 to expose the semiconductor feature 228, the second etching process 266 is performed to selectively remove the semiconductor feature 228 exposed by the trench 264 to vertically extend the trench 264. The extended trench 264 may be referred to as the trench 264′. The second etching process 266 is performed to selectively remove the semiconductor feature 228 without substantially etching the dielectric layer 258, the STI feature 207, and the optional isolation layer 230. That is, the selective removal of the semiconductor feature 228 is self-aligned and the extended portion of the trench 264′ has a width substantially equal to the width W1 of the semiconductor feature 228. Even if there is an alignment overlay during the formation of the trench 264 (shown in FIG. 13B), the self-aligned extended portion of the trench 264′ will not expose the gate structure 240. Thus, overlay window of the photolithography process for forming the trench 264 (shown in FIG. 13B) may be relaxed. The second etching process 266 may be a selective wet etching process or a selective dry etching process. In some embodiments, the second etching process 266 is an isotropic etching process. In some other embodiments, the second etching process 266 is an anisotropic etching process. The second etching process 266 may employ the etchant solution that includes a mixture of ammonia hydroxide (NH₄OH), hydrogen peroxide (H₂O₂), and water (H₂O) to selectively remove the semiconductor feature 228.

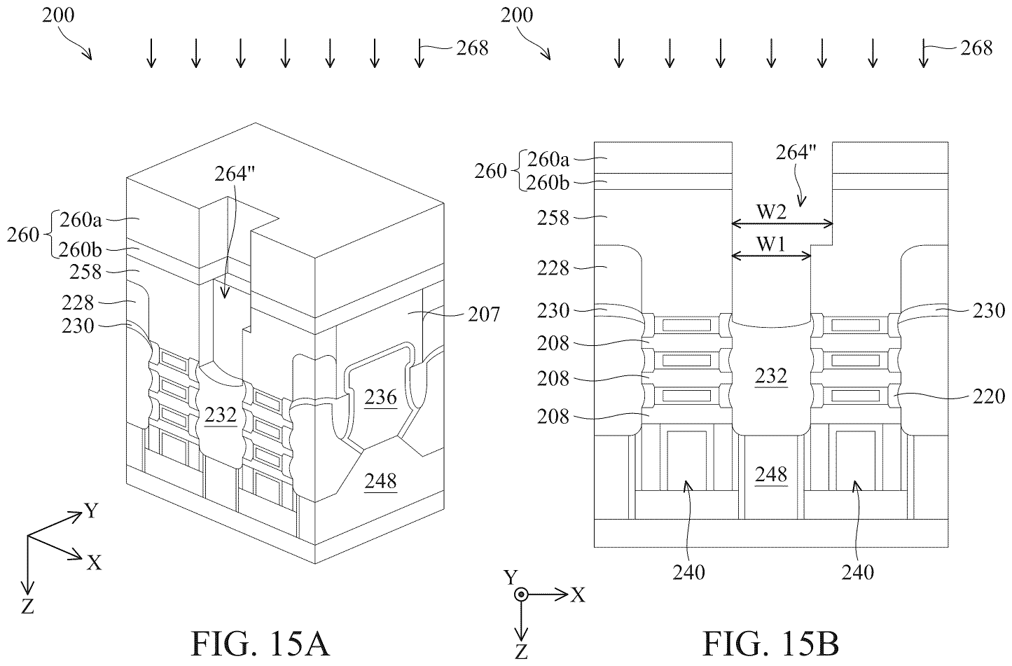

Referring to FIGS. 1 and 15A-15B, method 100 includes a block 126 where a third etching process 268 is performed to selectively remove the isolation layer 230. In embodiments where the semiconductor structure 200 includes the isolation layer 230, the third etching process 268 is performed to selectively remove the isolation layer 230 to expose the bottom surface of the source/drain feature 232. In some embodiments, etchant of the third etching process 268 may slightly etch the source/drain feature 232 under the isolation layer 230. For example, the source/drain feature 232 may have a bottom surface that curves inward after the performing of the third etching process 268. The trench 264′ after the removal of the isolation layer 230 may be referred to as the trench 264″. For embodiments where the where the semiconductor structure 200 does not include the isolation layer 230, the third etching process 268 will be omitted.

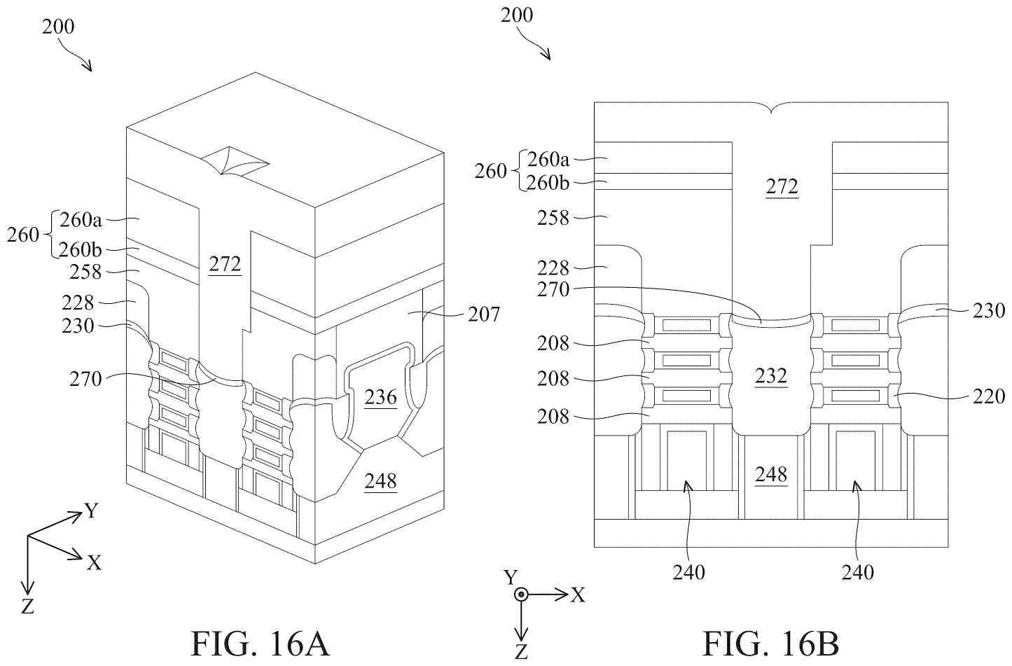

Referring to FIGS. 1 and 16A-16B and 17A-17B, method 100 includes a block 128 where a silicide layer 270 and a backside via 274 is formed in the trench 264″. After exposing the source/drain feature 232, a silicide layer 270 is formed on the exposed surface of the source/drain feature 232. To form the silicide layer 270, a metal layer (not explicitly shown) is deposited over the exposed surfaces of the source/drain feature 232 and an anneal process is performed to bring about silicidation reaction between the metal layer and the source/drain feature 232. Suitable metal layer may include titanium, tantalum, nickel, cobalt, or tungsten. In embodiments where the metal layer includes nickel and the source/drain feature 232 includes silicon germanium, the silicide layer 270 includes nickel silicide, nickel germanide, and nickel germanosilicide. The silicide layer 270 generally tracks the shape of the exposed source/drain feature 232. In some embodiments, the silicide layer 270 may include TiSi, CrSi, TaSi, MoSi, ZrSi, HfSi, ScSi, Ysi, HoSi, TbSi, GdSi, LuSi, DySi, ErSi, and/or YbSi. Excess portions of the metal layer that does not form the silicide layer 270 may be removed. In an embodiment, a thickness of the silicide layer 270 may be in a range between about 1 nm and about 10 nm to effectively reduce contact resistance without causing electrical short. As shown in FIGS. 16A-16B, a conductive layer 272 is then deposited over the back side of semiconductor structure 200, including in the trench 264″ and on the silicide layer 270. The conductive layer 272 may include aluminum (Al), copper (Cu), tungsten (W), cobalt (Co), ruthenium (Ru), nickel (Ni), molybdenum (Mo) or other suitable materials and may be formed by any suitable deposition processes (e.g., CVD). In some embodiments, a barrier layer may be formed before depositing the conductive layer 272. The barrier layer may include titanium, tantalum, TiN, TaN, or other suitable materials. With reference to FIGS. 17A-17B, a planarization process, such as a chemical mechanical polish (CMP) process, may be then performed to remove excess materials over the dielectric layer 258 to define a final structure of the backside via 274.

The backside via 274 has a planar bottom surface that is coplanar with the bottom surface of the dielectric layer 258 and a top surface in direct contact with the silicide layer 270 thereunder. In this illustrated embodiment represented by FIG. 17B, the backside via 274 has a first portion 274a spanning the width W2 and a second portion 274b spanning the width W1 less than the W2. The width W2 may be in a range between about 10 nm and about 50 nm. If the width W2 is greater than 50 nm, risk of having electrical short between the backside via and its adjacent conductive features may be increased, and device area may be increased. If the width W2 is less than 10 nm, parasitic resistance associated with the backside via may be too high, disadvantageously affecting the device performance. The width W1 may be in a range between about 8 nm and about 40 nm. If the width W1 is greater than 40 nm, risk of having electrical short between the backside via and its adjacent conductive features may be increased, and device area may be increased. If the width W1 is less than 8 nm, parasitic resistance associated with the backside via may be too high, disadvantageously affecting the device performance.

In an embodiment, the backside via 274 has an asymmetric profile. More specifically, in the cross-sectional view, the first portion 274a overhangs the second portion 274b on one side and aligns with the second portion 274b on the opposite side. That is, one sidewall surface of the backside via 274 has a step-wise profile. In this embodiment, the first portion 274a of the backside via 274 is vertically overlapped with the inner spacer feature 220. A height of the backside via 274 is in a range between about 5 nm and about 70 nm. If the height is less than 5 nm, parasitic capacitance between power lines in the backside interconnect structure and the gate structure may be too large, thereby disadvantageously affecting the device performance and reliability; if the height is greater than 70 nm, it would be challenging to form a deep trench 264 and performing deposition processes to form satisfactory layers in the deep backside via opening, and resultant backside via may have large parasitic resistance. In some other embodiments, the CMP process in block 128 removes the first layer 260a of the patterned dielectric structure 260 and does not remove the second layer 260b, and the resultant backside via 274 would thus have a planar top surface that is coplanar with the top surface of the second layer 260b. As a result, along the Y direction, the backside via 274 may extend over a portion of the STI feature 207 exposed in the trench 264″.

Referring to FIG. 1, method 100 includes a block 130 where further processes are performed. Such further processes may include forming a second interconnect structure (not shown) over the back side of the semiconductor structure 200. The second interconnect structure may have a structure similar to the first interconnect structure 252. For example, the second interconnect structure may include multiple intermetal dielectric (IMD) layers and multiple metal lines or contact vias in each of the IMD layers. In some instances, the IMD layers and the ILD layer 236 may share similar composition. The metal lines and contact vias in each IMD layer may be formed of metal, such as aluminum, tungsten, ruthenium, or copper. In some embodiments, the metal lines and contact vias may be lined by a barrier layer to insulate the metal lines and contact vias from the IMD layers and to prevent electro-migration. Because the second interconnect structure is formed over the back side of the semiconductor structure 200, the second interconnect structure may also be referred to as a backside interconnect structure.

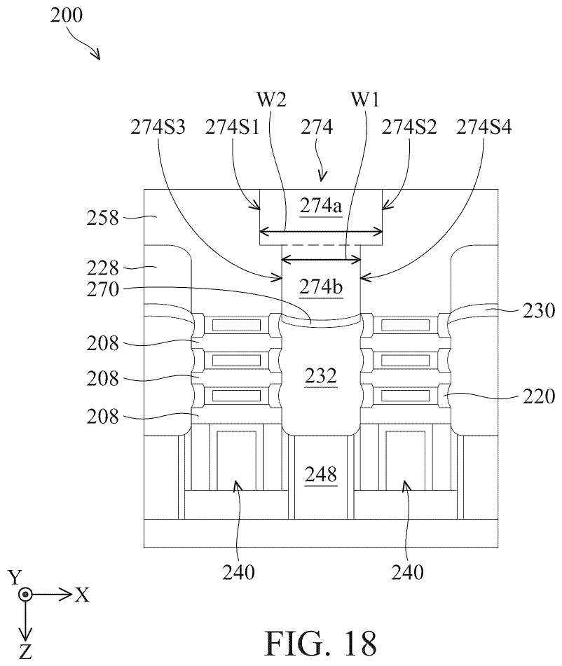

In the above embodiment described with reference to FIGS. 17A-17B, the backside via 274 has an asymmetric profile, and the first portion 274a of the backside via 274 overhangs the second portion 274b of the backside via 274 on one side and aligns with the second portion 274b of the backside via 274 on the other side. In an alternative embodiment represented by FIG. 18, the backside via 274 may have a symmetric profile. For example, the first portion 274a of the backside via 274 overhangs the second portion 274b of the backside via 274 on both two sides. More specifically, in this alternative embodiment, the first portion 274a includes a sidewall 274S1 and a sidewall 274S2 opposite the sidewall 274S1, and the second portion 274b includes a sidewall 274S3 and a sidewall 274S3 opposite the sidewall 274S3. The sidewall 274S1 is offset from the sidewall 274S3, and the sidewall 274S2 is offset from the sidewall 274S4. In other words, each sidewall of the backside via 274 has a step-wise profile. The first portion 274a may be vertically overlapped with two inner spacer features 220 formed on opposite sides of the silicide layer 270. A distance between sidewall 274S3 and sidewall 274S1 is substantially equal to a distance between sidewall 274S4 and sidewall 274S2. In another alternative embodiment, the backside via 274 has an asymmetric profile, and the distance between sidewall 274S3 and sidewall 274S1 is different than the distance between sidewall 274S4 and sidewall 274S2.

In the above embodiments described with reference to FIGS. 1-18, the semiconductor layer 204 is substantially fully removed during the fabrication process in the method 100. In some alternative embodiments, the semiconductor layer 204 may be partially removed such that the gate structures 240 may not be damaged by etchant of the etching process implemented to etch the semiconductor layer 204. FIG. 19 illustrates a flow chart of an alternative method 300 for forming a semiconductor structure 400 having a backside via, according to one or more aspects of the present disclosure. Method 300 is described below in conjunction with FIGS. 20-26B, which are fragmentary cross-sectional views of a semiconductor structure 400 at different stages of fabrication according to embodiments of method 300.

Referring to FIGS. 19, 1, and FIGS. 2A-10B, method 300 includes blocks 102, 104, 106, 108, 110, 112, 114, 116, and 118 of method 100. Repeated description of operations in blocks 102, 104, 106, 108, 110, 112, 114, 116, and 118 are omitted for reason of simplicity. For ease of description, semiconductor structure 200 represented by FIGS. 10A-10B will be referred to as semiconductor structure 400 in this alternative embodiment.

Referring to FIGS. 19 and 20, method 300 includes a block 302 where the semiconductor layer 204 of the substrate 201 is selectively recessed. After the semiconductor structure 400 is flipped over and planarized (shown in FIGS. 10A-10B), with reference to FIG. 20, an etching process is performed to selectively etch the semiconductor layer 204 with respect to the semiconductor features 228, the STI features 207, and the gate structures 240. The etching process for selectively etching the semiconductor layer 204 may be a selective wet etching process or a selective dry etching process. An exemplary selective dry etching process may implement CF₄, NF₃, Cl₂, HBr, other suitable gases and/or plasmas, and/or combinations thereof. In this embodiment, the semiconductor layer 204 is partially removed to form an opening 254′. As illustrated by FIG. 20, the opening 254′ exposes the semiconductor features 228 and the semiconductor layer 204. In other words, a portion of the sidewall surface of the semiconductor feature 228 is covered by the recessed semiconductor layer 204, and the opening 254′ exposes another portion of the sidewall surface of the semiconductor feature 228 not covered by the recessed semiconductor layer 204. The height of the semiconductor layer 204 may be adjusted by controlling the duration of the etching process performed in block 302. In this illustrated embodiment, after the performing of the etching process in block 302, a height of the semiconductor layer 204 is less than a height of the semiconductor feature 228.

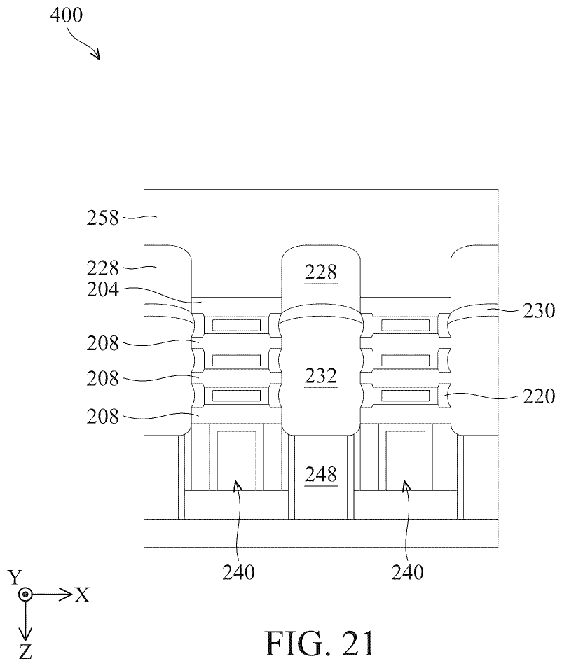

Referring to FIGS. 19 and 21, method 300 includes a block 304 where a dielectric layer 258 is formed over the recessed substrate (i.e., the recessed semiconductor layer 204). The formation and composition of the dielectric layer 258 have been described above with reference to FIGS. 12A-12B, and repeated description is omitted for reason of simplicity. The dielectric layer 258 is spaced apart from the gate structure 240 by the semiconductor layer 204.

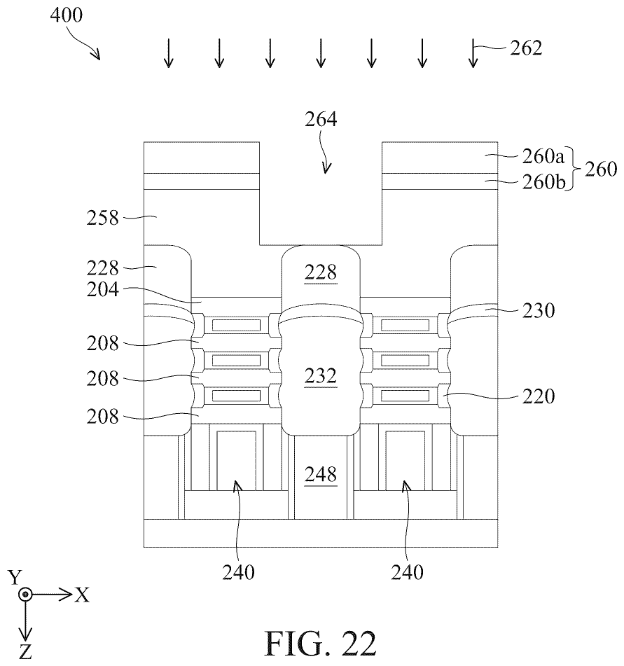

Referring to FIGS. 19 and 22, method 300 includes a block 306 where a first etching process 262 is performed to form a trench 264 in the dielectric layer 258 to expose the semiconductor feature 228. Operations in block 306 are similar to the operations in block 122 described above with reference to FIGS. 1 and 13A-13B, and repeated description is thus omitted for reason of simplicity.

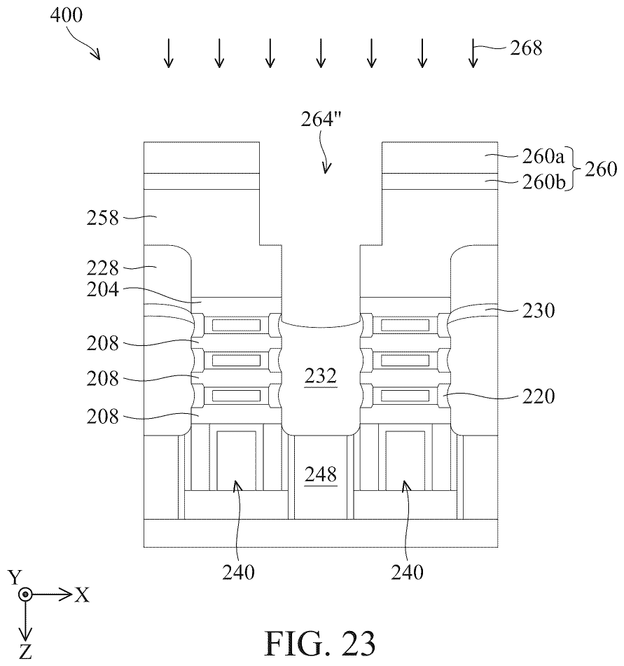

Referring to FIGS. 19 and 23, method 300 includes a block 308 where a second etching process 266 is performed to selectively remove the semiconductor feature 228. Operations in block 308 are similar to the operations in block 124 described above with reference to FIGS. 1 and 14A-14B, and repeated description is thus omitted for reason of simplicity. For embodiments in which the semiconductor structure 400 includes the optional isolation layer 230, a third etching process 268 is performed to selectively remove the isolation layer 230. The third etching process 268 has been described with reference to FIGS. 1 and 15A-15B, and repeated description is thus omitted for reason of simplicity.

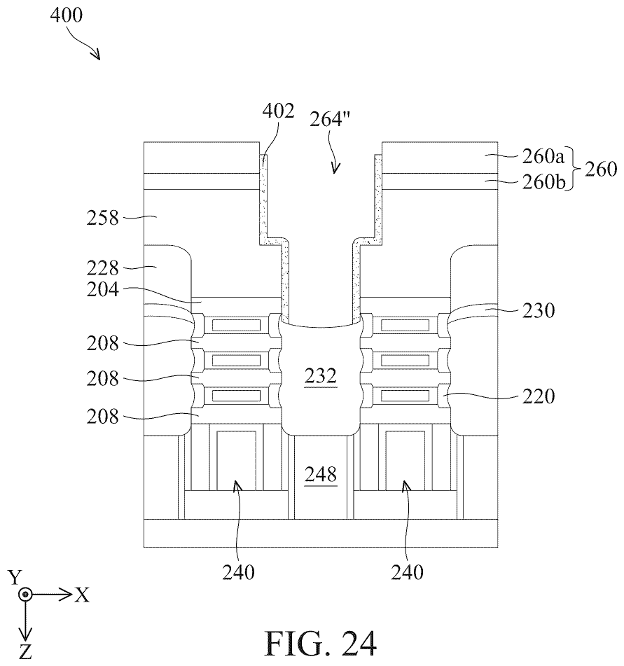

Referring to FIGS. 19 and 24, method 300 includes a block 310 where a dielectric barrier layer 402 is formed in the trench 264″. In an exemplary process, to form the dielectric barrier layer 402, a dielectric material layer is deposited over the back side of the semiconductor structure 400, including in the trench 264′, and is then etched back to only cover sidewalls of the trench 264″ and expose the source/drain feature 232. The dielectric barrier layer 402 may include silicon nitride or other suitable materials. The dielectric barrier layer 402 provides isolation between the recessed semiconductor layer 204 and conductive features (e.g., the backside via 274 and the silicide layer 270) formed in the trench 264″.

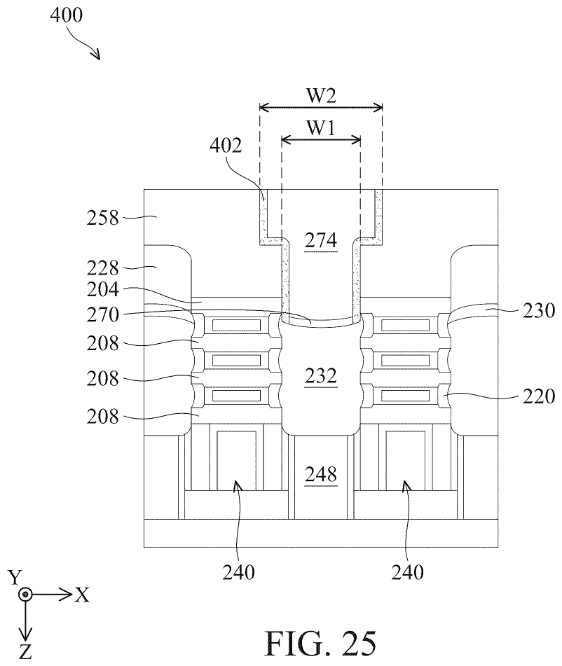

Referring to FIGS. 19 and 25, method 300 includes a block 312 where a silicide layer 270 and a backside via 274 are formed in the trench 264″. After forming the dielectric barrier layer 402, the silicide layer 270 and the backside via 274 are formed in the trench 264″. Operations in block 312 are similar to the operations in block 128 described above with reference to FIGS. 1, 16A-16B and 17A-17B, and repeated description is thus omitted for reason of simplicity. The semiconductor structure 400 represented by FIG. 25 is substantially similar to the semiconductor structure 200 represented by FIG. 18, and main differences between the semiconductor structure 400 and the semiconductor structure 200 include that, the semiconductor structure 400 includes the semiconductor layer 204 disposed between the dielectric layer 258 and the gate structure 240 and the dielectric barrier layer 402 disposed between the backside via 274 and the dielectric layer 258.

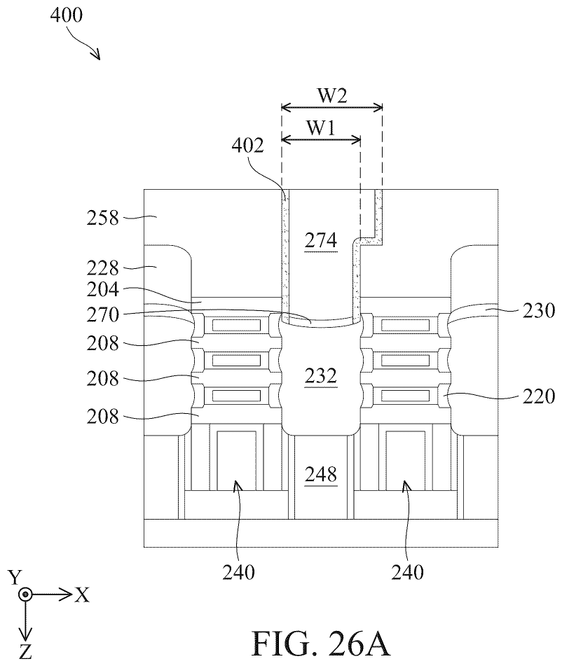

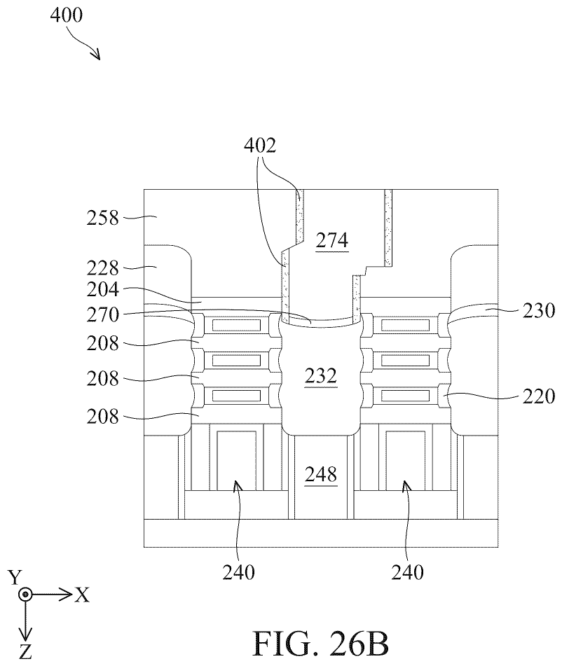

The backside via 274 represented by FIG. 25 has a symmetric profile similar to that described with reference to FIG. 18. In some alternative embodiments represented by FIGS. 26A and 26B, the backside via 274 has an asymmetric profile. With respect to FIG. 26A, the backside via 274 having an asymmetric profile that is similar to that described with reference to FIG. 17B. With respect to FIG. 26B, the backside via 274 having an asymmetric profile. For example, a portion of the backside via 274 closer to the silicide layer 270 is offset from a portion of the backside via 274 further away from the silicide layer 270. The backside via 274 in this illustrated embodiment may have a uniform width or a non-uniform width from bottom to top. The dielectric barrier layer 402 extends along vertical portions of the sidewall surfaces of the backside via 374. The dielectric barrier layer 402 provides isolation between the backside via 274 and the recessed semiconductor layer 204.

After forming the backside via 274, referring to FIG. 19, method 300 includes a block 314 where further processes are performed. Operations in block 314 are similar to the operations in block 130 described above with reference to FIG. 1, and repeated description is thus omitted for reason of simplicity.

In embodiments described above with reference to FIGS. 1-26B, the semiconductor layer 204 of the substrate 201 is either fully or partially replaced by the dielectric layer 258, and the backside via 274 extends through the dielectric layer 258. In another alternative embodiment, the backside via 614 extends through the semiconductor layer 204 of the substrate 201. FIG. 27 illustrates a flow chart of an alternative method 500 for forming a semiconductor structure 600 having a backside via 614 extending through the semiconductor layer 204, according to one or more aspects of the present disclosure. Method 500 is described below in conjunction with FIGS. 28A-36, which are fragmentary cross-sectional views of the semiconductor structure 600 at different stages of fabrication according to embodiments of method 500.

Referring to FIGS. 27, 1, and FIGS. 2A-10B, method 300 includes blocks 102, 104, 106, 108, 110, 112, 114, 116, and 118 of method 100. For ease of description, semiconductor structure 200 represented by FIGS. 10A-10B will be referred to as semiconductor structure 600 in this alternative embodiment.

Referring to FIGS. 27, 28A-28B and 29A-29B, method 500 includes a block 502 where a first etching process 602 is performed to form a trench 604 in the substrate 201 to expose the semiconductor feature 228. With reference to FIGS. 28A-28B, after the semiconductor structure 600 is flipped over and planarized to remove the carrier layer 202 and the insulator layer 203 of the substrate 201 to expose the semiconductor layer 204, a patterned dielectric structure 260 is formed over the back side of the semiconductor structure 600. The formation and composition of the patterned dielectric structure 260 has been described above with reference to FIGS. 13A-13B, and repeated description is omitted for reason of simplicity. In this illustrated embodiment, the patterned dielectric structure 260 includes an opening 601 exposing a portion of the semiconductor layer 204 and a portion of the STI feature 207 (shown in FIG. 28A).

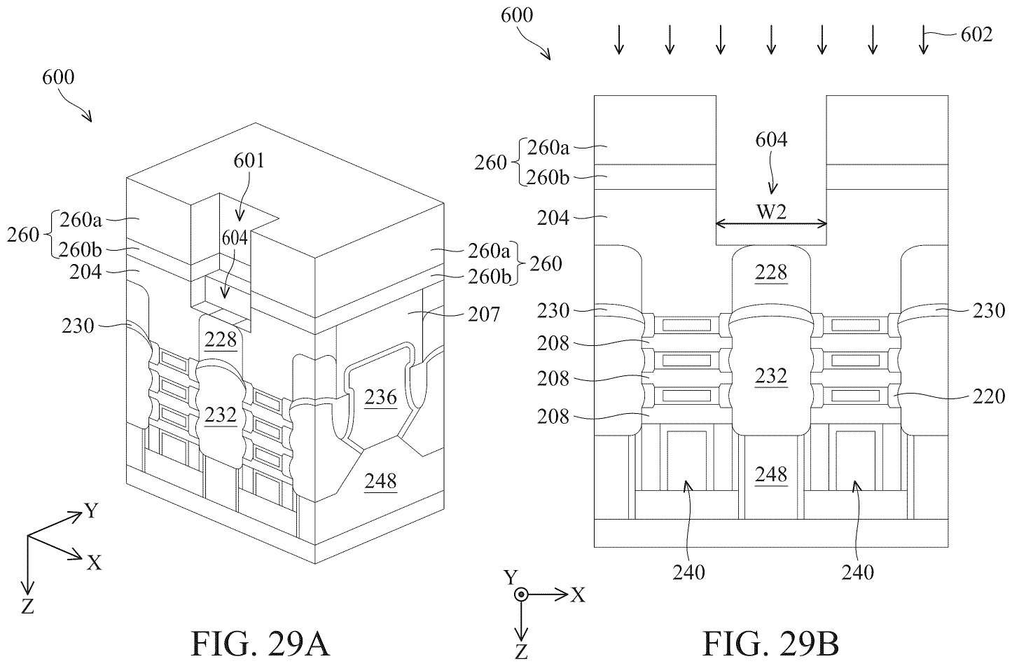

With reference to FIGS. 29A-29B, while using the patterned dielectric structure 260 as an etch mask, a first etching process 602 is performed to the semiconductor structure 600 to form a trench 604 extending into the semiconductor layer 204. The trench 604 exposes the semiconductor feature 228 and spans a width W2 greater than the width W1 of the semiconductor feature 228. In this illustrated embodiment, the trench 604 also exposes a portion of the semiconductor layer 204 surrounding the semiconductor feature 228. The first etching process 602 may be an anisotropic dry etch. In an embodiment, the first etching process 602 may implement an oxygen-containing gas, hydrogen, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof.

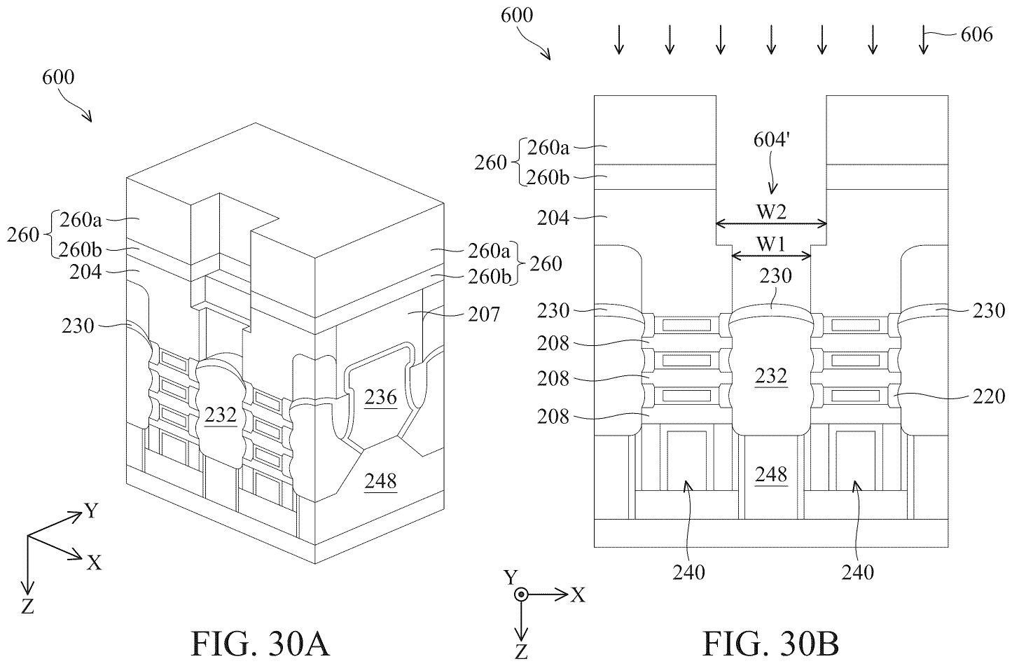

Referring to FIGS. 27 and 30A-30B, method 500 includes a block 504 where a second etching process 606 is performed to selectively remove the semiconductor feature 228 to vertically extend the trench 604. The extended trench 604 may be referred to as the trench 604′. The second etching process 606 is performed to selectively remove the semiconductor feature 228 without substantially etching the semiconductor layer 204, the STI feature 207, and the optional isolation layer 230. That is, the selective removal of the semiconductor feature 228 is self-aligned and the extended portion of the trench 604′ has a width substantially equal to the width W1 of the semiconductor feature 228. In these embodiments, the second etching process 606 may be a selective wet etching process or a selective dry etching process. In an embodiment, the second etching process 606 may employ the etchant solution that includes a mixture of ammonia hydroxide (NH₄OH), hydrogen peroxide (H₂O₂), and water (H₂O) to selectively remove the semiconductor feature 228.

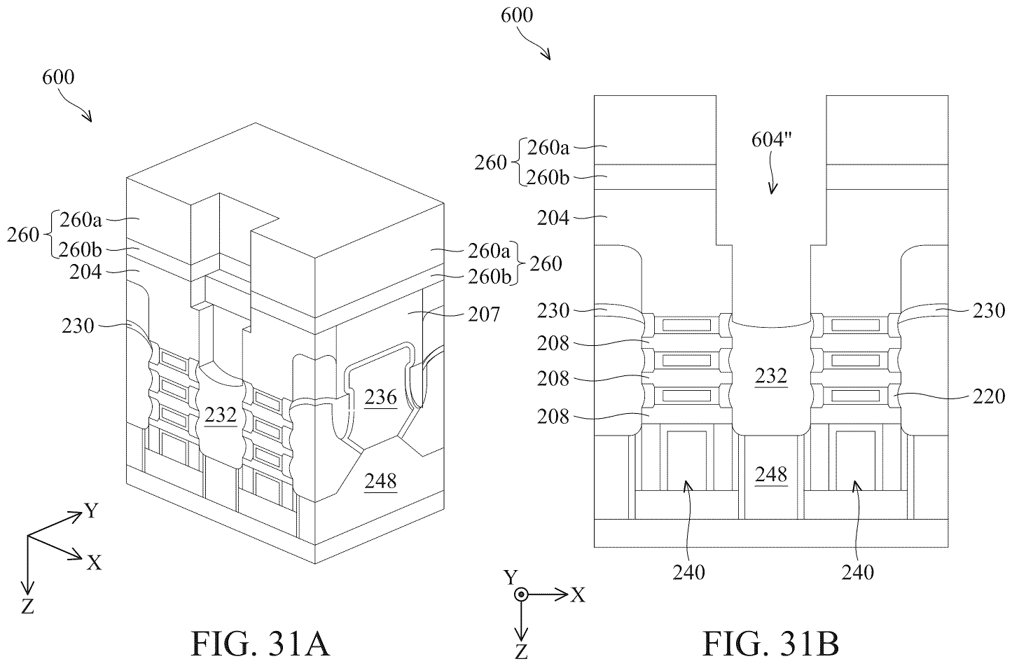

In embodiments where the semiconductor structure 600 includes the isolation layer 230 exposed by the trench 604′, as represented by FIGS. 31A-31B, an additional etching process is performed to selectively remove the isolation layer 230 to expose the bottom surface of the source/drain feature 232. In some embodiments, etchant of the additional etching process may slightly etch the source/drain feature 232 under the isolation layer 230. For example, the source/drain feature 232 may have a bottom surface that curves inward after the performing of the additional etching process. The trench 604′ after the removal of the isolation layer 230 may be referred to as the trench 604″. For embodiments where the semiconductor structure 600 does not include the isolation layer 230, the additional etching process will be omitted.

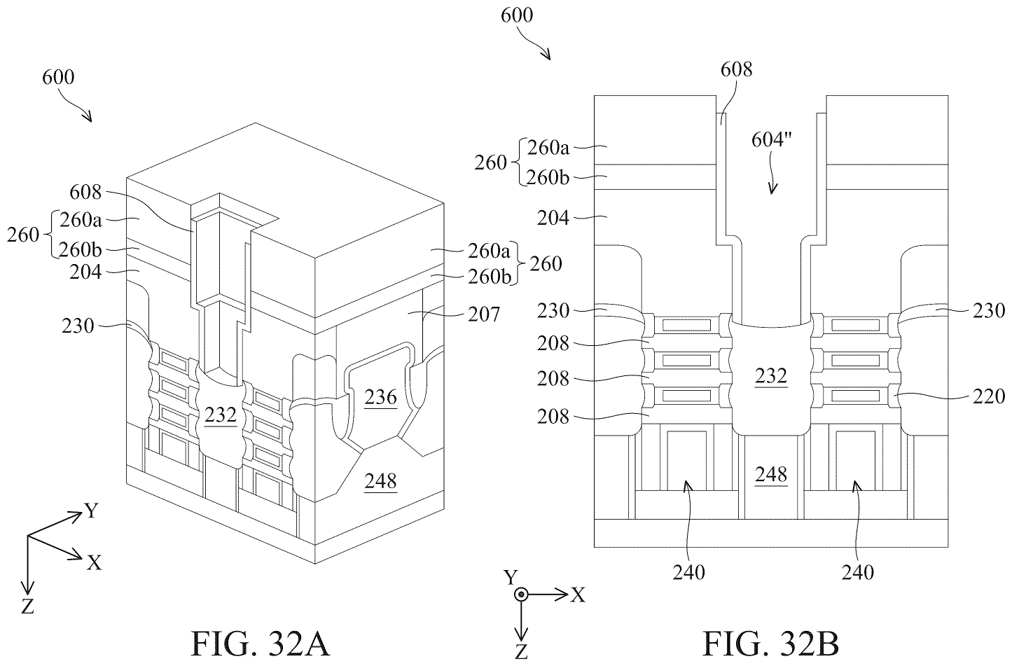

Referring to FIGS. 27 and 32A-32B, method 500 includes a block 506 where a dielectric barrier layer 608 is formed in the trench 604″. The formation and composition of the dielectric barrier layer 608 may be similar to those of the dielectric barrier layer 402 described with reference to FIG. 24, and repeated description is omitted for reason of simplicity.

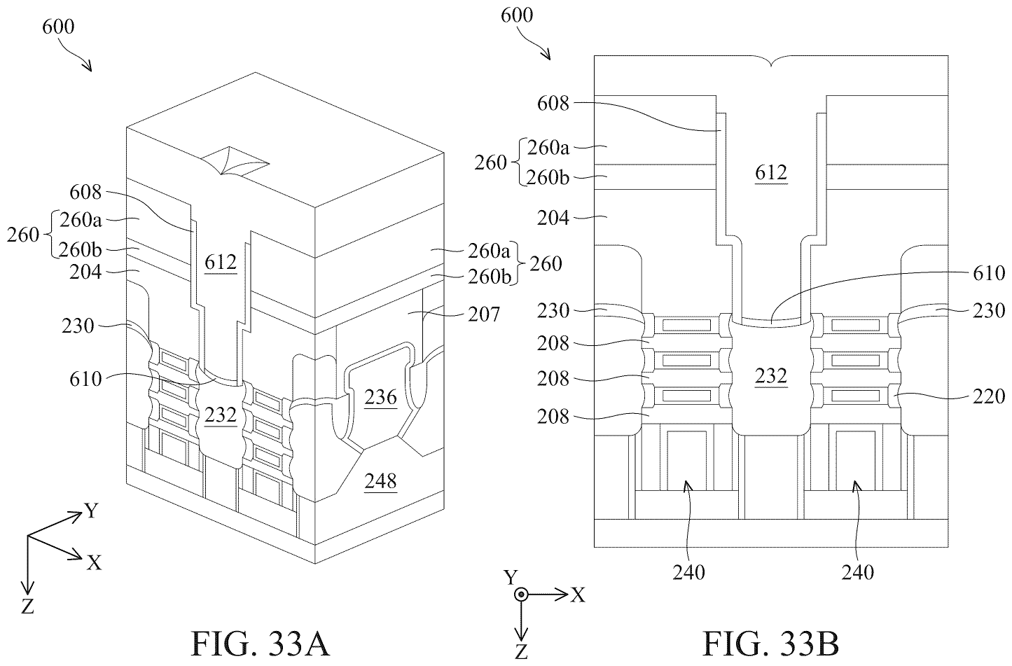

Referring to FIGS. 27, 33A-33B, and 34A-34B, method 500 includes a block 508 where a silicide layer 610 and a backside via 614 are formed in the trench 604″. After exposing the source/drain feature 232, a silicide layer 610 is formed on the exposed surface of the source/drain feature 232. The formation and composition of the silicide layer 610 may be similar to those of the silicide layer 270 described with reference to FIGS. 16A-16B, and repeated description is thus omitted for reason of simplicity. As shown in FIGS. 33A-33B, a conductive layer 612 is then deposited over the back side of semiconductor structure 600, including in the trench 604″ and on the silicide layer 610. The formation and composition of conductive layer 612 may be similar to those of the conductive layer 272 described with reference to FIGS. 16A-16B, and repeated description is thus omitted for reason of simplicity. Similarly, in some embodiments, a barrier layer may be formed before depositing the conductive layer 612. The barrier layer may include titanium, tantalum, TiN, TaN, or other suitable materials. Along the Y direction, the conductive layer 612 extends over a portion of the STI feature 207 exposed in the trench 604″.

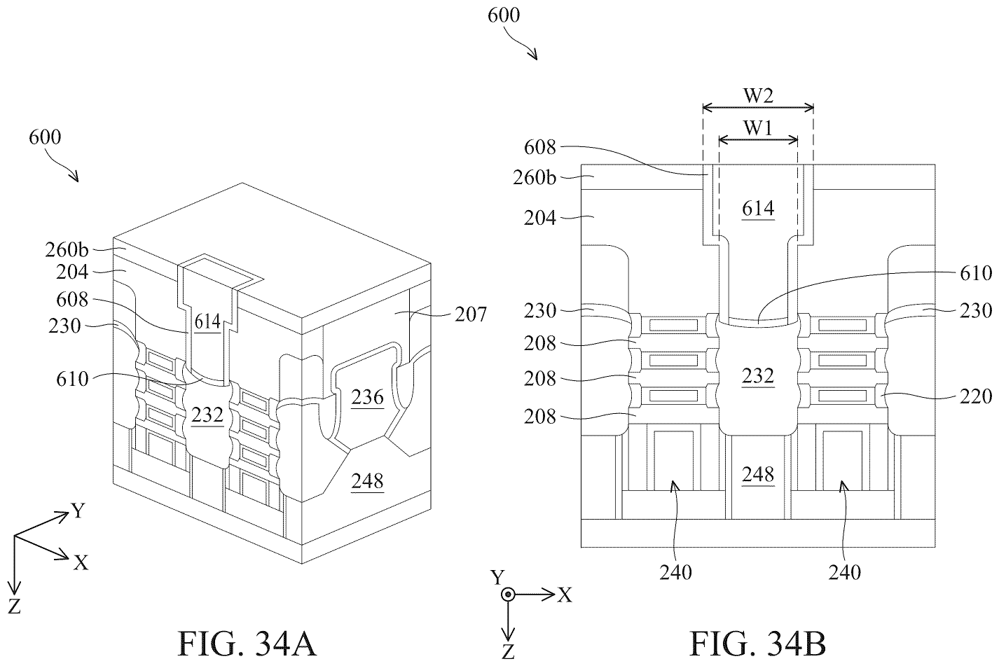

With reference to FIGS. 34A-34B, a planarization process, such as a chemical mechanical polish (CMP) process, may be then performed to remove excess materials over the back side of the second layer 260b to define a final structure of the backside via 614. Along the Y direction, the backside via 614 extends over a portion of the STI feature 207 exposed in the trench 604″. The backside via 614 has a planar bottom surface that is coplanar with the bottom surface of the second layer 260b and a top surface in direct contact with the silicide layer 610 thereunder. In this illustrated embodiment represented by FIGS. 34A-34B, the backside via 614 has a first portion spanning the width W2 and a second portion spanning the width W1 less than the W2. In an embodiment, the backside via 614 has a symmetric profile. More specifically, the first portion of the backside via 614 overhangs the second portion of the backside via 614 on both two sides. That is, each of the two sidewall surfaces of the backside via 274 has a step-wise profile. In another embodiment, the backside via 614 has an asymmetric profile where the first portion of the backside via 614 overhangs the second portion of the backside via 614 on both two sides with different extents.

Referring to FIG. 27, method 500 includes a block 510 where further processes are performed. Operations in block 510 are similar to the operations in block 130 described above with reference to FIG. 1, and repeated description is thus omitted for reason of simplicity.

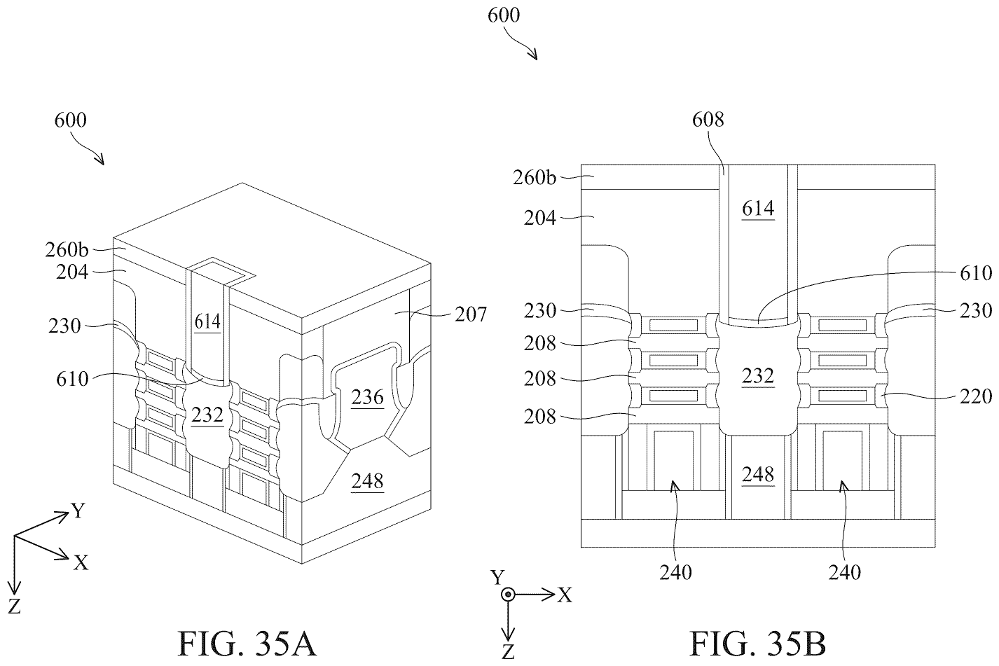

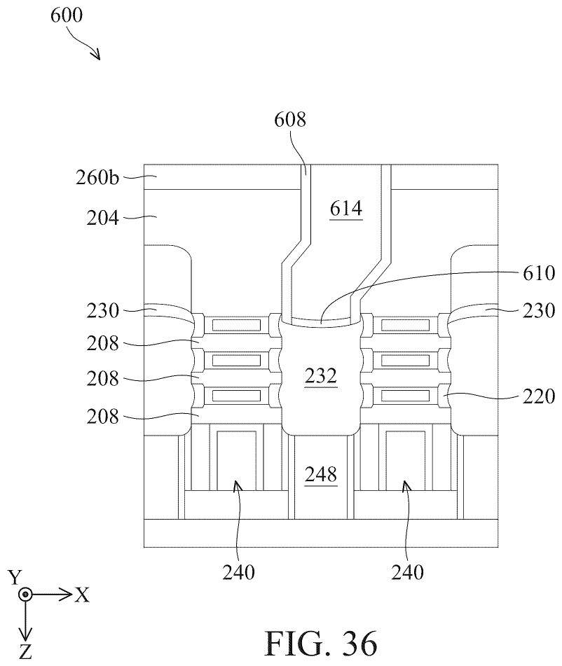

In the above embodiments described with reference to FIG. 35B, the backside via 614 has a first portion and a second portion with different widths. In another alternative embodiment represented by FIGS. 35A-35B, the backside via 614 may have a substantially uniform width (e.g., W1) from bottom to top and substantially vertical sidewalls. In another alternative embodiment represented by FIG. 36A, the backside via 614 may have an asymmetrical profile. For example, a portion of the backside via 614 closer to the silicide layer 610 is offset from a portion of the backside via 614 further away from the silicide layer 610. The backside via 614 in this illustrated embodiment may have a uniform width or a non-uniform width from bottom to top.

Embodiments of the present disclosure provide advantages. Methods of the present disclosure form self-aligned backside vias without forming a deep trench in the source/drain region. Thus, overlay window of the photolithography process for forming the trench may be relaxed to facilitate the scaling down of the gate-to-gate pitch.

The present disclosure provides for many different embodiments. Semiconductor structures and methods of fabrication thereof are disclosed herein. In one exemplary aspect, the present disclosure is directed to a method. The method includes receiving a structure comprising a plurality of channel members disposed over a substrate, a gate structure wrapping around each of the plurality of channel members, and a source/drain feature adjacent to the plurality of channel members, wherein the source/drain feature is disposed over a semiconductor feature extending into the substrate. The method also includes source/drain feature is disposed over a semiconductor feature extending into the substrate, replacing the substrate with a dielectric layer, forming a mask having an opening exposing a portion of the dielectric layer, removing the portion of the dielectric layer to form a trench exposing the semiconductor feature, selectively removing the semiconductor feature to vertically extend the trench, and forming a via in the extended trench.

In some embodiments, the via has a first portion spanning a first width and a second portion spanning a second width greater than the first width. In some embodiments, one sidewall surface of the first portion of the via is offset from one sidewall surface of the second portion of the via. In some embodiments, the structure may also include an isolation layer disposed between the source/drain feature and the semiconductor feature, and the method may also include, after the selectively removing of the semiconductor feature, selectively removing the isolation layer. In some embodiments, the trench spans a width greater than a width of the semiconductor feature. In some embodiments, the structure may also include an isolation feature disposed between the plurality of channel members and another plurality of channel members, the method may also include, before the replacing of the substrate with the dielectric layer, reducing a thickness of the substrate from its back to expose the isolation feature. In some embodiments, the trench may also expose a portion of the isolation feature, and the via may be vertically overlapped with the isolation feature. In some embodiments, the source/drain feature is a first source/drain feature, and the semiconductor feature is a first semiconductor feature, the structure may also include a second source/drain feature over a second semiconductor feature, and a height of the via is greater than a height of the second semiconductor feature. In some embodiments, a composition of the semiconductor feature may be different than a composition of the substrate.

In another exemplary aspect, the present disclosure is directed to a method. The method includes forming a sacrificial feature in a substrate, forming a source/drain feature over the sacrificial feature and protruding from the substrate, planarizing the substrate from its back to reduce its thickness, performing a first etching process to selectively remove the substrate without substantially etching the sacrificial feature, forming a dielectric layer adjacent to and under the sacrificial feature, performing a second etching process to form a trench in the dielectric layer to expose the sacrificial feature, performing a third etching process to selectively remove the sacrificial feature, and forming a conductive feature in the trench.

In some embodiments, the trench spans a width greater than a width of the sacrificial feature. In some embodiments, the sacrificial feature is a semiconductor layer having a composition different than the substrate. In some embodiments, the method may also include, before forming the source/drain feature, forming an isolation layer on the sacrificial feature, and after the performing of the third etching process, performing a fourth etching process to selectively remove the sacrificial feature. In some embodiments, the forming of the conductive feature in the trench may include forming a silicide layer under and coupled to the source/drain feature, depositing a conductive layer to fill the trench, and planarizing the conductive layer to expose the dielectric layer. In some embodiments, in a cross-sectional view, the conductive feature may have an asymmetric profile. In some embodiments, the method may also include forming a source/drain contact over the source/drain feature.

In yet another exemplary aspect, the present disclosure is directed to a semiconductor structure. The semiconductor structure includes a plurality of nanostructures over a dielectric layer, a gate structure wrapping around each of the plurality of nanostructures and over the dielectric layer, a source/drain feature coupled to at least one of the plurality of nanostructures, and a via extending through the dielectric layer to couple to the source/drain feature, wherein, in a cross-sectional view, the via has an asymmetric profile.

In some embodiments, the semiconductor structure may also include another source/drain feature coupled to at least one of the plurality of nanostructures, and a semiconductor feature under the source/drain feature and embedded in the dielectric layer, wherein a height of the via is greater than a height of the semiconductor feature. In some embodiments, the via has a first portion and a second portion under the first portion, a width of the first portion is substantially equal to a width of the semiconductor feature and less than a width of the second portion. In some embodiments, the semiconductor structure may also include an isolation layer disposed between the semiconductor feature and the another source/drain feature.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
receiving a structure comprising:
a plurality of channel members disposed over a substrate,
a gate structure wrapping around each of the plurality of channel members, and
a source/drain feature adjacent to the plurality of channel members, wherein the source/drain feature is disposed over a semiconductor feature extending into the substrate;
replacing the substrate with a dielectric layer;
forming a mask having an opening exposing a portion of the dielectric layer;
removing the portion of the dielectric layer to form a trench exposing the semiconductor feature;
selectively removing the semiconductor feature to vertically extend the trench; and
forming a via in the extended trench.

2. The method of claim 1, wherein the via has a first portion spanning a first width and a second portion spanning a second width greater than the first width.

3. The method of claim 2, wherein one sidewall surface of the first portion of the via is offset from one sidewall surface of the second portion of the via.

4. The method of claim 1, wherein the structure further comprises an isolation layer disposed between the source/drain feature and the semiconductor feature, the method further comprising:
after the selectively removing of the semiconductor feature, selectively removing the isolation layer.

5. The method of claim 1, wherein the trench spans a width greater than a width of the semiconductor feature.

6. The method of claim 1, wherein the structure further comprises an isolation feature disposed between the plurality of channel members and another plurality of channel members, the method further comprising:
before the replacing of the substrate with the dielectric layer, reducing a thickness of the substrate from its back to expose the isolation feature.

7. The method of claim 6, wherein the trench further exposes a portion of the isolation feature, and the via is vertically overlapped with the isolation feature.

8. The method of claim 1, wherein the source/drain feature is a first source/drain feature, and the semiconductor feature is a first semiconductor feature, the structure further comprises a second source/drain feature over a second semiconductor feature, and wherein a height of the via is greater than a height of the second semiconductor feature.

9. The method of claim 1, wherein a composition of the semiconductor feature is different than a composition of the substrate.

10. A method, comprising:
forming a sacrificial feature in a substrate;
forming a source/drain feature over the sacrificial feature and protruding from the substrate;
planarizing the substrate from its back to reduce its thickness;
performing a first etching process to selectively remove the substrate without substantially etching the sacrificial feature;
forming a dielectric layer adjacent to and under the sacrificial feature;
performing a second etching process to form a trench in the dielectric layer to expose the sacrificial feature;
performing a third etching process to selectively remove the sacrificial feature; and
forming a conductive feature in the trench.

11. The method of claim 10, wherein the trench spans a width greater than a width of the sacrificial feature.

12. The method of claim 10, wherein the sacrificial feature is a semiconductor layer having a composition different than the substrate.

13. The method of claim 10, further comprising:
before forming the source/drain feature, forming an isolation layer on the sacrificial feature; and
after the performing of the third etching process, performing a fourth etching process to selectively remove the sacrificial feature.

14. The method of claim 13, wherein the forming of the conductive feature in the trench comprises:
forming a silicide layer under and coupled to the source/drain feature;
depositing a conductive layer to fill the trench; and
planarizing the conductive layer to expose the dielectric layer.

15. The method of claim 13, wherein, in a cross-sectional view, the conductive feature has an asymmetric profile.

16. The method of claim 13, further comprising:
forming a source/drain contact over the source/drain feature.

17. A semiconductor structure, comprising:
a plurality of nanostructures over a dielectric layer;
a gate structure wrapping around each of the plurality of nanostructures and over the dielectric layer;
a source/drain feature coupled to at least one of the plurality of nanostructures; and
a via extending through the dielectric layer to couple to the source/drain feature, wherein, in a cross-sectional view, the via has an asymmetric profile.

18. The semiconductor structure of claim 17, further comprising:
another source/drain feature coupled to at least one of the plurality of nanostructures; and
a semiconductor feature under the source/drain feature and embedded in the dielectric layer,
wherein a height of the via is greater than a height of the semiconductor feature.

19. The semiconductor structure of claim 18, wherein the via has a first portion and a second portion under the first portion, a width of the first portion is substantially equal to a width of the semiconductor feature and less than a width of the second portion.

20. The semiconductor structure of claim 18, further comprising:
an isolation layer disposed between the semiconductor feature and the another source/drain feature.
